(19) United States
(12) Patent Application Publication
(10) Pub. No.: US 2012/0299221 A1
(43) Pub. Date: Nov. 29, 2012

(54) MAGNETIC REVERSIBLY ATTACHED TEMPLATE (MRAT) AND USES THEREFOR

(75) Inventors: Andries Zijlstra, Nashville, TN (US); William Ashby, Nashville, TN (US); John Wikswo, Brentwood, TN (US); Philip Samson, Nashville, TN (US)

(73) Assignee: VANDERBILT UNIVERSITY, Nashville, TN (US)

(21) Appl. No.: 13/513,785

(22) PCT Filed: Dec. 2, 2010
(86) PCT No.: PCT/US10/58699

§ 371 Date: Aug. 13, 2012

Related U.S. Application Data
(60) Provisional application No. 61/266,358, filed on Dec. 3, 2009.

(51) Int. Cl. B29C 67/24; C23C 14/28

(52) U.S. Cl. 264/437; 425/3

(57) ABSTRACT

The magnetic reversibly attached template (MRAT) are solid devices made of biocompatible material containing a magnetic material. These devices can be made in any shape using microfabrication, milling, and molding and can be positioned and secured using magnetic forces. The applications of the M RAT encompass the patterning of biological and non-biological materials including cells, nucleic acids, peptides, proteins, aqueous solutions, polymers, rubbers, and other reagents on solid surfaces.

### CROSS REFERENCE TO RELATED APPLICATIONS

This application claims priority to U.S. provisional application No. 61/266,358, filed Dec. 3, 2009, which is incorporated herein by reference in its entirety.

### FIELD OF THE INVENTION

Embodiments of the invention comprise stencils that utilize magnetic forces to attach to surfaces used for biological system analysis including a glass cover slip, polystyrene multi-well plate, microfluidic devices, or microarrays and to surfaces containing micropatterns including silicon wafers, glass slides, and polished metal. The magnetically attachable template provides microscale resolution and overcomes the limitations of current stencils used in biology and allows rapid creation of macroscale features on micropatterned surfaces. Compositions that constitute the stencil are also provided.

### BACKGROUND

There is a continual push to fabricate structures with smaller dimensions for use in biology, engineering, electronics, optics, chemistry, and biochemistry. The dimensions of these structures ranging from less than a few hundred nanometers (nano-structures) to several micrometers (micro-structures), and a maximum of a few millimeters (macro-structures). While methods for patterning such features is a central focus for a number of emerging technologies, patterning structures for these three dimensions with an accuracy that is ≦1 micron is typically difficult to carry out reproducibly and economically. Moreover, creating devices that contain all three dimension (nano-, micro-, and macro-structures) is particularly difficult because they are generally created with distinct techniques. Despite progress in the fabrication of micro- and nano-structures, many biological uses of such technology are untapped and techniques for creating macroscale features on micropatterned surfaces are still needed.

In biological applications the physical positioning of cells, proteins and three-dimensional matrices at micrometer resolution is highly desirable. Unlike chemicals and physical structures biological entities from proteins to cells function properly in a very narrow range of conditions. Moreover, a cell has autonomous behavior that changes in response to alterations in its environments. These aspects make it extremely difficult to perform reproducible, non-destructive, and accurate patterning of biological entities (cells and proteins).

### SUMMARY

This Summary is provided to present a summary of the invention to briefly indicate the nature and substance of the invention. It is submitted with the understanding that it will not be used to interpret or limit the scope or meaning of the claims.

in a preferred embodiment, a system in which a removable template is attached for purposes of molding shaping, patterning, printing, separating, and retaining biological and non-biological materials: comprising a magnetic reversibly attachable template and a magnet. In another preferred embodiment, the composition of the template, comprises polydimethylsiloxane, polymethylmethacrylate, polyacrylic acid, polyacrylamide, polymethacrylamide, polyethacrylamide, polyalkacrylamides, polyamides, polyacrylonitrile, polybutadiene, polycaprolactone, polyethylene, polypropylene, polystyrene, polydivinylbenzene, polyethylene glycol, polypropylene glycol, polylactide, polyglycolide, polyornithine, polyvinyl acetate, polyvinyl alcohol, polyvinyl chloride, polyvinyl isobutyl ether, polyvinyl methyl ether, polyurethane, and polyvinylpyrrolidone, polymeric organosilicon, copolymers thereof, polytetrafluoroethylene, poly(p-xylylene) polymers, glass, rubber, ferrimagnetic, ferromagnetic, or paramagnetic particles.

In another preferred embodiment, the composition of the magnetically attachable template comprises polydimethylsiloxane and ferromagnetic, ferromagnetic and/or paramagnetic particles. Preferably, the ferromagnetic, ferromagnetic and/or paramagnetic particles comprise magnetite (Fe(II,III) oxide), hematite, chromite, iron tritetraoxide (Fe₃O₄), γ-sesquioxide (γ-Fe₂O₃), MnZn-ferrite, NiZn-ferrite, YFe-gamet, GaFe-gamet, Ba-ferrite, Sr-ferrite; iron, manganese, cobalt, nickel, chromium; alloys of iron, manganese, cobalt, nickel, or combinations thereof. In some embodiments, the ferrimagnetic or paramagnetic particles are between about 0.001 μm to about 10 μm in diameter. In another embodiment, the ferrimagnetic or paramagnetic particles are about 5 μm or less in diameter.

In another preferred embodiment, the template composition comprises at least about 5% ferrimagnetic or paramagnetic particles by weight.

in another preferred embodiment, the magnetically attachable template is reversibly attached to a biological device or culture unit, the template comprising a patterned surface having a plurality of shapes, sizes, base elements, top elements, protrusions, recesses, dividers, microchannels, or combinations thereof. The magnetically attachable template when reversibly attached to the biological device or culture unit forms a desired imprinted pattern or chamber for analyzing biological samples, separating and patterning cells and molecules. In some aspects, the chamber comprises one or more dividers, wherein the dividers are at least about 0.01 μm wide wherein the dividers extend from a first opposing face of two opposing faces from a central axis of a main plate to a peripheral edge thereof. In some aspects, at least two dividers are perpendicular to each other. In another embodiment, the magnetically attachable template comprises dividers, protruding elements or combinations thereof.

In another preferred embodiment, the magnetically attachable template comprises a flat surface having at least one aperture, wherein each aperture is separated from another aperture by varying distances.

In another preferred embodiment, imprinted template pattern nucleic acids or peptides on a unit are accomplished via contact or liquid printing. Liquid printing comprises applying proteins to a surface in a liquid and reversibly attaching the stencil comprising a desired pattern thereby forming microchannels and reservoirs for the liquids.

In another preferred embodiment, the magnetically attachable template forms chambers comprising: void spaces, micro wells, three-dimensional culture spaces, fluid barriers, movable flaps, porous dividers, microfluidic channels, micro-printed patterns, or combinations thereof.

In another preferred embodiment, the biological sample imprinted as a desired pattern or cultured in the chamber is analyzed by one or more assays, comprising: X-rays, microchip analysis, radiation, immunoassays, photography, electron microscopy, microscopy, photography, radioactivity, chemical or mechanical assays.

In another preferred embodiment, the magnetically attachable template is patterned by contacting a master template comprising a desired pattern with a soluble composition comprising the stencil, the pattern being produced by a process comprising: casting, molding, etching through a mask, photolithography, x-ray lithography, nano-imprint lithography (NIL), or combinations thereof.

In preferred embodiments, the magnetically attachable template is reversibly attachable to a biological device or culture unit in that a magnetic force is exerted on the stencil, wherein the magnetic force is generated by at least one of: a permanent magnet, temporary magnet, an electromagnet or combinations thereof. In some embodiments, the magnetic force is configured by an electromagnetic force generation unit for causing a magnetic force to act on the magnetically attachable template for attachment to the biological device or culture unit for analyzing biological samples, separating and patterning cells and molecules. In preferred embodiments, the magnetically attachable template is magnetically reversibly attached to a biological apparatus. Examples of biological apparatus comprises: tissue culture plates, multi-well plates, biochips, microchips, or high throughput screening apparatus.

In another preferred embodiment, a magnetically reversibly attachable template comprising: polydimethylsiloxane, polymethylmethacrylate, polyacrylic acid, polyacrylamide, polymethacrylamide, polyethacrylamide, polyalkacrylamides, polyamides, polyacrylonitrile, polybutadiene, polycaprolactone, polyethylene, polypropylene, polystyrene, polydivinylbenzene, polyethylene glycol, polypropylene glycol, polylactide, polyglycolide, polyornithine, polyvinyl acetate, polyvinyl alcohol, polyvinyl chloride, polyvinyl isobutyl ether, polyvinyl methyl ether, polyurethane, and polyvinylpyrrolidone, polymeric organosilicon, polytetrafluoroethylene, poly(p-xylylene) polymers, copolymers thereof, glass, rubber, ferrimagnetic, ferromagnetic, or paramagnetic particles.

In another preferred embodiment, the magnetically reversibly attachable template having ferromagnetic, ferromagnetic, and/or paramagnetic particles comprise magnetite (Fe(II, III) oxide), hematite, chromite, iron tritetraoxide (Fe₃O₄), γ-sesquioxide (γ-Fe₂O₃), MnZn-ferrite, NiZn-ferrite, YFe-gamet, GaFe-gamet, Ba-ferrite, Sr-ferrite; iron, manganese, cobalt, nickel, chromium; alloys of iron, manganese, cobalt, nickel, or combinations thereof. In a preferred embodiment, the template is molded to reversibly attach to a biological device or culture unit, the stencil comprising a patterned surface having a plurality of shapes, sizes, base elements, top elements, protrusions, recesses, dividers, microchannels, or combinations thereof in other embodiments, the template when reversibly attached to the biological device or culture unit forms a desired imprinted pattern or chamber for analyzing biological samples, separating and patterning cells and molecules, the chamber comprising: void spaces, micro wells, three-dimensional culture spaces, fluid barriers, movable flaps, porous dividers, microfluidic channels, micro-printed patterns, or combinations thereof.

In another preferred embodiment, a method of manufacturing a magnetic reversibly attached template comprising: contacting a master template comprising a desired pattern with a stencil composition; contacting the template with a semi-liquid or liquid stencil composition, curing and molding the stencil; and, manufacturing a magnetically attachable stencil. Preferably, the template composition, comprises polydimethylsiloxane, polymethylmethacrylate, polyacrylic acid, polyacrytamide, polymethacrylamide, polyethacrylamide, polyalkacrylamides, polyamides, polyacryionitrile, polybutadiene, polycaprotactone, polyethylene, polypropylene, polystyrene, polydivinylbenzene, polyethylene glycol, polypropylene glycol, polylactide, polyglycolide, polyornithine, polyvinyl acetate, polyvinyl alcohol, polyvinyl chloride, polyvinyl isobutyl ether, polyvinyl methyl ether, polyurethane, and polyvinylpyrrolidone, polymeric organosilicon, polytetrafluoroethylene, poly(p-xylylene) polymers, copolymers thereof, glass, rubber, ferrimagnetic, ferromagnetic, or paramagnetic particles. The ferromagnetic compound, ferromagnetic or paramagnetic particles comprise magnetite (Fe(II,III), hematite, chromite, iron tritetraoxide (Fe₃O₄), γ-sesquioxide (γ-Fe₂O₃), MnZn-ferrite, NiZn-ferrite, YFe-gamet, GaFe-gamet, Ba-ferrite, Sr-ferrite; iron, manganese, cobalt, nickel, chromium; alloys of iron, manganese, cobalt, nickel, or combinations thereof.

In another preferred embodiment, a high-throughput screening assay for analyzing nucleic acids or peptides comprises imprinting a chip with the systems or magnetic reversibly attached templates described or any variations thereof.

In another preferred a method of analyzing a sample comprises contacting the sample with the apparatus or the magnetic reversibly attached templates.

In another preferred embodiment, a method of producing large devices, comprising attaching magnetic reversibly attached templates (MRATS, MAtS) to a master plate; forming a desired pattern; and, producing large devices. The magnetic reversible attached templates (MRAT), are molded into shapes, dimensions, and designs as desired by an end user and a plurality of MRAT are attached to the master plate, wherein the MRATS are patterned onto the master plate when attached by magnets. In some embodiments, the master plate comprises a micro-fluidic template. The master template is optionally coated with a coating material comprising a polyvinyl alcohol.

Other aspects are described infra.

### BRIEF DESCRIPTION OF THE DRAWINGS

FIGS. 1A-1C is a schematic representation of one embodiment of a Star MRAT,

FIG. 1A shows a top view of the stencil. FIG. 1B shows a bottom view of the stencil. FIG. 1C shows a side view of the dividers.

FIGS. 2A, 2B is a schematic representation of other embodiments of a MRAT used as microwells.

FIGS. 3A-3C show a schematic representation of one embodiment of the stencil (MRAT) used as a chemotactic device. A central well is created inside the MRAT which contains a chemotactic agent (promotes migration of cells towards the source of the agent). The chemotactic agent is allowed to diffuse into the open space (into which the cells can migrate). The use of a wedge-shaped migration space (with the narrow end at the chemotactic wells and the wide end facing the incoming cells) causes the formation of a chemotactic gradient.

FIGS. 4A, 4B are a schematic representation of an embodiment of a magnetic reversibly attached template (MRAT). In this representation, the template comprises more than one well and different types of well-shapes. This type of MRAT can be used, for example, in the cell-cell communication studies between similar or different cell types, migration, response to stimuli, and so on.

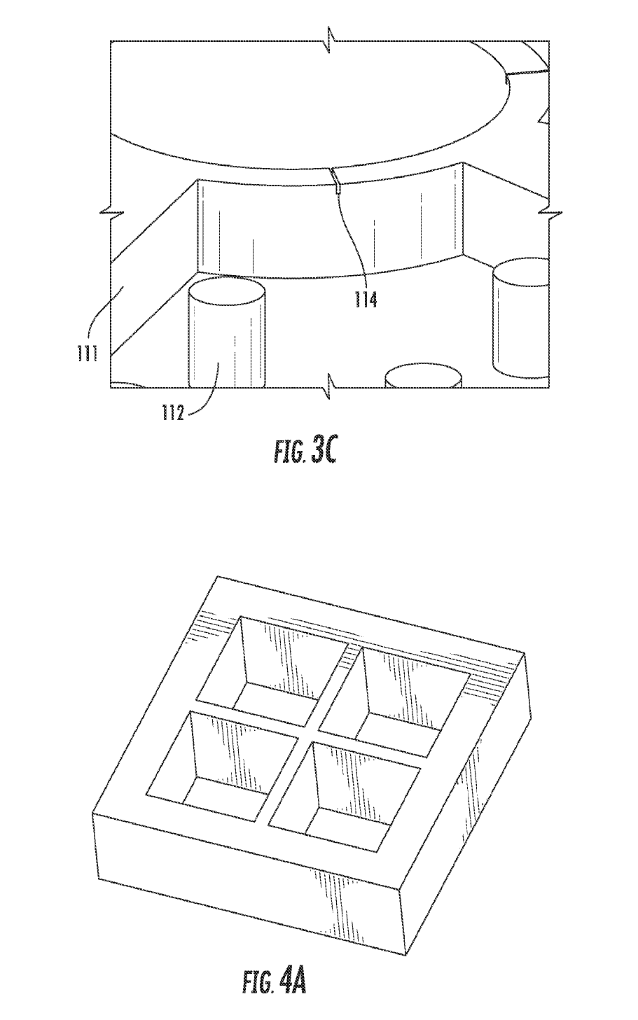

FIG. 5 is a schematic representation of another type of MRAT. This type of design can be used in cell migration studies, cell chemotaxis, response to different agents. For example different cell types can be placed in each well and an agent in the center, or any combination thereof.

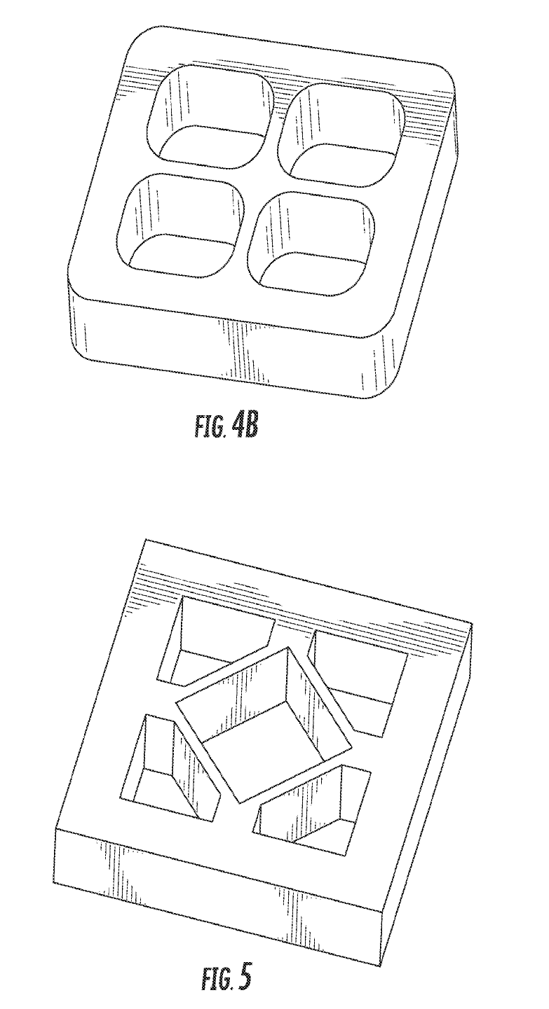

FIG. 6 is a schematic representation of another embodiment of MRAT. The chemoattractant can be placed in the center well 200 comprising microchannels 201, it can be layered with collagen or other matrix, cells can be placed on the collagen or in the solution.

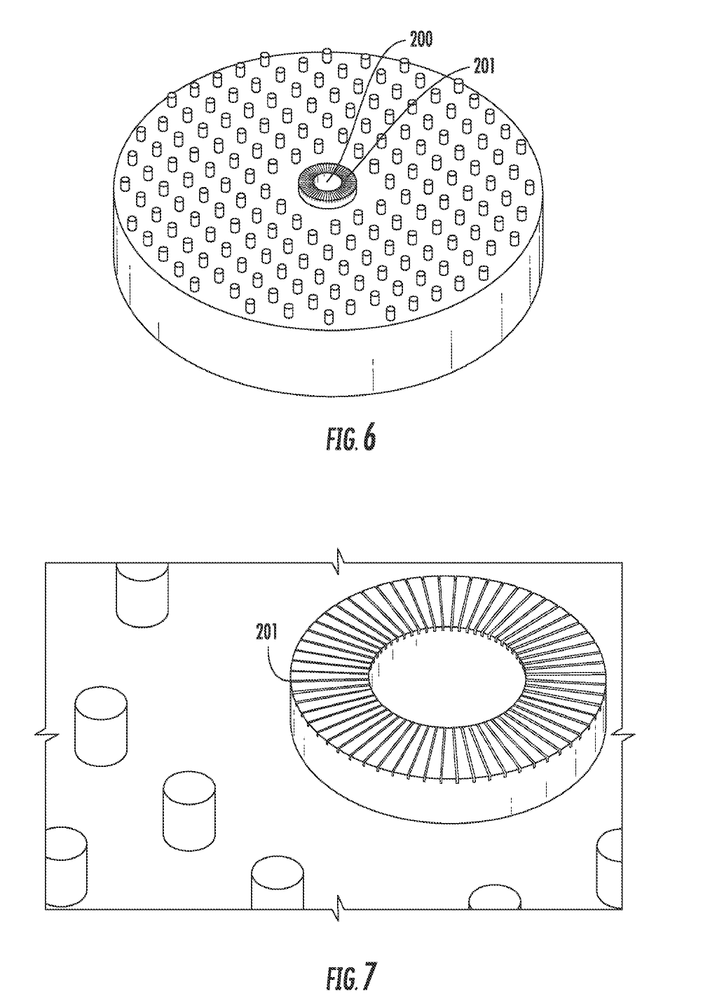

FIG. 7 is a schematic representation of a close up view of a microchannel 201.

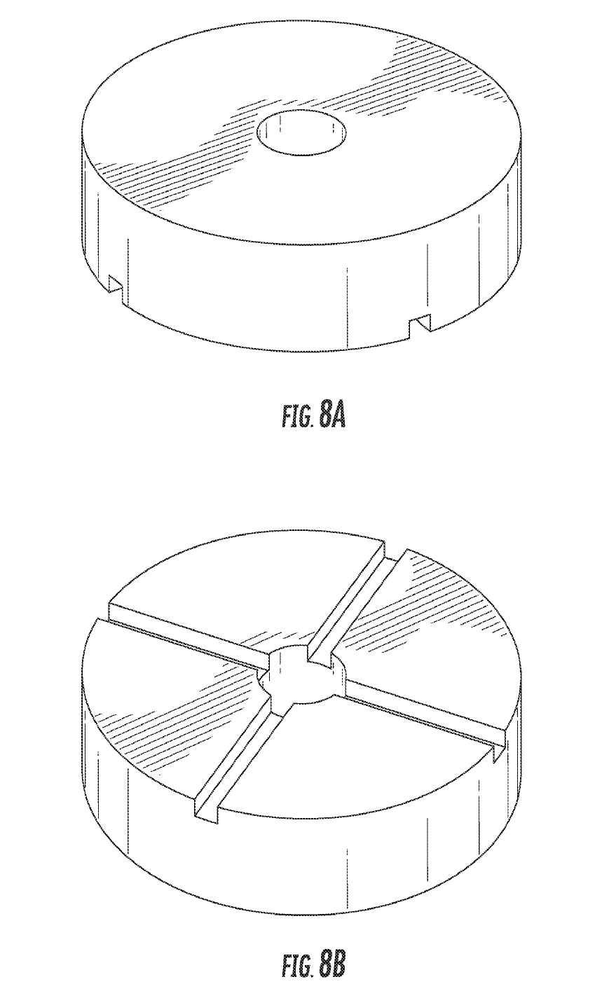

FIGS. 8A, 8B are a schematic representation showing an embodiment of a MRAT for use in protein printing. The solution containing a protein can be placed in the center well and the MRAT is placed in a well containing medium, PBS, saline etc.

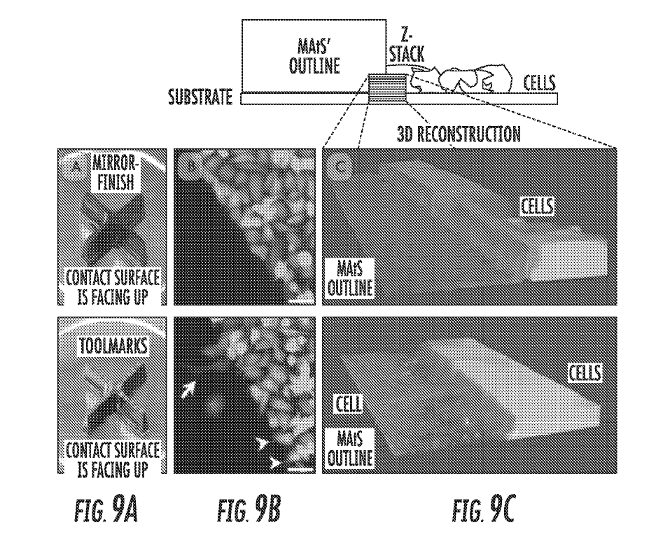

FIGS. 9A-9C show that micro-scale precision is needed to prevent cell protrusion. Aggressive cancer cells (HEN) were patterned on collagen-coated cover glass using MAtS coated with Alexa-555 antibody. Z-stacks to create 3D reconstruction of the interface. FIG. 9A shows representative images of production-quality MAtS (top) with the contact surface facing up show the mirror-finish contact surface compared to the toolmarks on the initial prototype (bottom). FIG. 9B: a smooth, flat contact surface is necessary to block cells from crawling (arrow) or extending protrusions (arrowheads) under the MAtS. Scale bar 50 μm. FIG. 9C: 3D reconstruction revealed that protrusions correlate with adhesion to MAtS.

FIGS. 10A-10E show that MAtS create reproducible confluent cell monolayers without damage. FIG. 10A: scratching denudes cell monolayers to create opposing sheets of cells often resulting in substrate irregularities (arrow) and cell debris (arrowhead). MAtS block cells to create opposing monolayers without disrupting the substrate or creating debris. Scale bar 50 μm. FIG. 10B: MAtS create reproducible initial widths both when repeating experiments with A549 cells (intra-experiment) and (FIG. 10C) when experimenting with different cell specifically A549 and murine mammary carcinoma cells (inter-experiment). Differences in initial width are minimized using MAtS while remaining significant. FIG. 10D: HEp3 cells migrate on collagen-coated glass from MAtS but only within the initial 60 μm area when scratched. FIG. 10E: Quantifying the maximum migration for the HEp3 cells showed continued migration using MAtS and inhibition of migration when scratched.

FIGS. 11A-11B show that MAtS maintain substrate during monolayer formation. FITC-gelatin substrates (green) remain intact after patterning fibronectin (red) with MAtS (top row) but are disrupted when scratching with a 200 μl pipette tip (bottom row). Interestingly scratches remove fibronectin but not FITC-gelatin in several areas (white arrow). FIG. 11B: FITC gelatin substrate after patterning cells with MAtS (top row) and after scratching (bottom row) to make opposing monolayers of cells.

FIGS. 12A-12D show the multifactorial nature of cell migration. Cell migration is a multifactorial process as seen by differences in migration from combinations of substrate conditions with different cell types, different levels of protein expression and different doses of antibody treatment. FIG. 12A: A549 cells migrate faster on collagen than t.c. plastic rates. Scratching A549 cells results in migration rates equivalent to or slightly faster than MAtS on t.c. plastic. FIG. 12B: HEp3 cells migrate faster on collagen coated substrates than on plastic. FIG. 12C: Murine mammary carcinoma cells expressing wild-type levels or lacking integrin α2 display opposite trends in migration rates on fibronectin and collagen versus plastic. Wild-type cells plated onto fibronectin and collagen migrated on slower on plastic and α2^{-/-} cells migrate faster on plastic. FIG. 12D: Inhibition of HEp3 cell migration by anti-CD151 treatment is enhanced by intact collagen. Disruption of the collagen substrate by scratching reduces sensitivity to anti-CD151 treatment.

FIGS. 13A-13D show the collective cell migration onto micropatterned proteins revealed matrix preference. FIG. 13A: HEp3 cells (green) prefer collagen coated plastic over bovine serum albumin (bright red). Images were collected immediately after removing MAtS (top, hr 0) and again eight hours (hr 8) later (bottom). FIG. 13B: Cell distributions across BSA and collagen lanes are plotted as average green intensity values over distance in μm.

FIGS. 14A-14B show the gelatin-coated polyacrylamide substrates. FIG. 14A: MAtS enabled cell patterning on elastic polyacrylamide substrates coated with gelatin (left column). Comparison of elastic (10 kPa) polyacrylamide and rigid (2-4 GPa) plastic revealed differences in cell morphology. On polyacrylamide cells were more protrusive and fibroblast like than on collagen-coated plastic. FIG. 14B: Migration was slower on the elastic polyacrylamide substrate.

### DETAILED DESCRIPTION

Embodiments of the invention comprise macroscale and microscale features for the patterning of cells, proteins, and three-dimensional matrices and still meet the strict requirements of biological applications.

In the fabrication of microscale devices, macroscale features interface with the micropatterned area, wherein the area is large, usually for introduction of materials. Prior to this invention, macroscale features were often created after the fact by punching holes or gluing on connectors. Though initially designed for use in biological applications termed herein as Magnetic Reversibly Attached Templates (MRAT) or in the alternative, Magnetically Attachable Stencils (MAtS), also function as magnetically attachable, removable macroscale features on micropatterned surfaces.

Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. The present invention is not limited by the illustrated ordering of acts or events, as some acts may occur in different orders and/or concurrently with other acts or events. Furthermore, not all illustrated acts or events are required to implement a methodology in accordance with the present invention.

### DEFINITIONS

The terminology used herein is for the purpose of describing particular embodiments only and is not intended to be limiting of the invention. As used herein, the singular forms “a”, “an” and “the” are intended to include the plural forms as well, unless the context clearly indicates otherwise. Furthermore, to the extent that the terms “including”, “includes”, “having”, “has”, “with”, or variants thereof are used in either the detailed description and/or the claims, such terms are intended to be inclusive in a manner similar to the term “comprising.”

The term “about” or “approximately” means within an acceptable error range for the particular value as determined by one of ordinary skill in the art, which will depend in part on how the value is measured or determined, i.e., the limitations of the measurement system. For example, “about” can mean within 1 or more than 1 standard deviation, per the practice in the art. Alternatively, “about” can mean a range of up to 20%, preferably up to 10%, more preferably up to 5%, and more preferably still up to 1% of a given value. Alternatively, particularly with respect to biological systems or processes, the term can mean within an order of magnitude, preferably within 5-fold, and more preferably within 2-fold, of a value. Where particular values are described in the application and claims, unless otherwise stated the term “about” meaning within an acceptable error range for the particular value should be assumed.

### Magnetic Reversibly Attached Templates (MRAT)/Magnetically Attachable Stencils (MAtS)

In biological applications of cell culture, the physical positioning of cells, proteins, and three-dimensional matrices at micrometer resolution is highly desirable. Currently this is achieved using two methods: 1) printing protein or cells by direct application of liquid materials in a defined pattern, and 2) applying a stencil that excludes cells or proteins when they are subsequently applied to the culture surface or alternatively stamps the protein where the stencil makes contact. Both methods yield patterned applications. In general, the first method requires high resolution technologies not routinely available to the cell biologist. The second method requires the application of a clamping force or the self-adhesion of the stencil to the culture surface. Techniques relying on self-adhesion of the stencil to the substrate are less obtrusive but not suitable for patterning on top of physiological matrices (such as fibronectin, collagen, and laminin) under the wet conditions of cell culture. Conversely, those relying on external force generally obstruct access to the cell culture and/or require use of specific cell culture dishes.

In contrast to any previous systems or compositions, the current invention, inter alia, provides a stencil that utilizes magnetic force to attach to any cell culture surface, such as a glass cover slip, silicone wafer, or polystyrene multi-well plate. The magnetic reversibly attached template (MRAT), also used interchangeably termed herein as Magnetically Attachable Stencils (MAtS), provides microscale resolution and overcomes the limitations of current stencils in cell culture. 1) Unlike current stencils that apply force from the top down, the magnets placed underneath the cell culture substrate provide a downward force by attracting the stencil toward the bottom of the culture substrate. This makes the stencil practically unobtrusive during cell culture procedures. 2) The magnetic force overcomes the limitations of self-adhesive stencils by providing the necessary force to attach and seal the stencil against wet, physiological matrices (such as fibronectin, collagen, and laminin). 3) The magnetic approach allows for the attachment of stencils to wet, protein-coated or cell-covered, glass or plastic surfaces, in contrast to, any currently available stencils, such as, for example, polydimethylsiloxane (PDMS) stencils that self-adhere only to clean, dry glass. 4) The magnetic force is uniform, accurate, and reproducible. This magnetic force is not influence/perturbed by the investigator during the application of the MAtS unlike existing technologies which use a “top-down” clamping force that must be controlled manually by the investigator.

Other advantages of the magnetic cell culture stencil in the marketplace are its ease of manufacture on large scales and low cost. The stencil can also be manipulated for immediate and direct application to a wide variety of conventional cell culture systems, such as protein-coated glass cover slips or multi-well plates. Specific examples of assays that can be adapted for use with MRAT (MAtS) include cell migration, chemotaxis, cell invasion and the like.

The following descriptions of MRAT are merely provided for illustrative purposes only and are not meant to be construed as being limiting in any way.

Microwell and Star MAT:

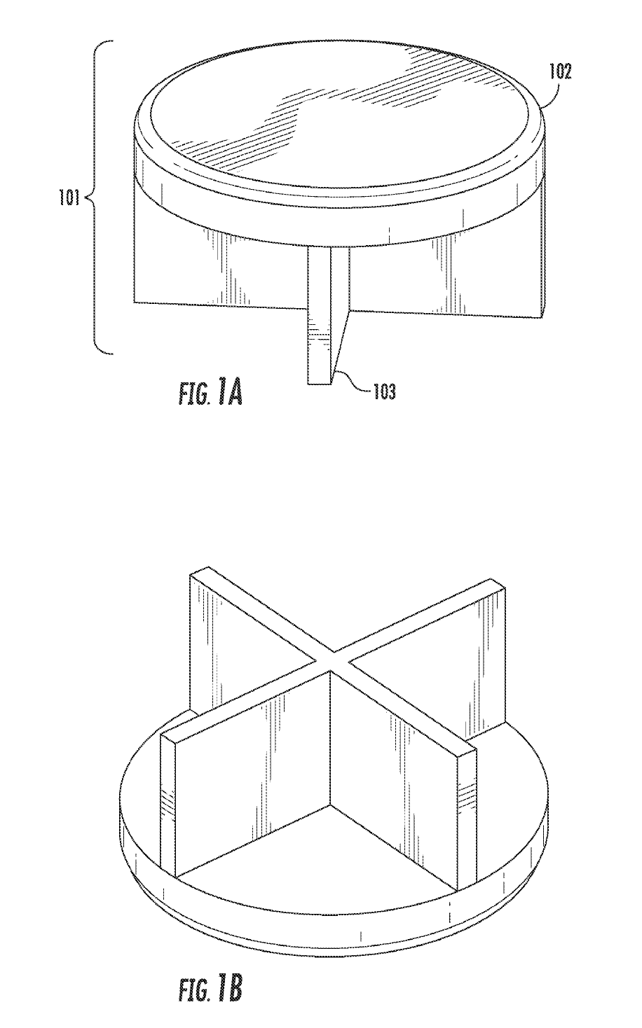

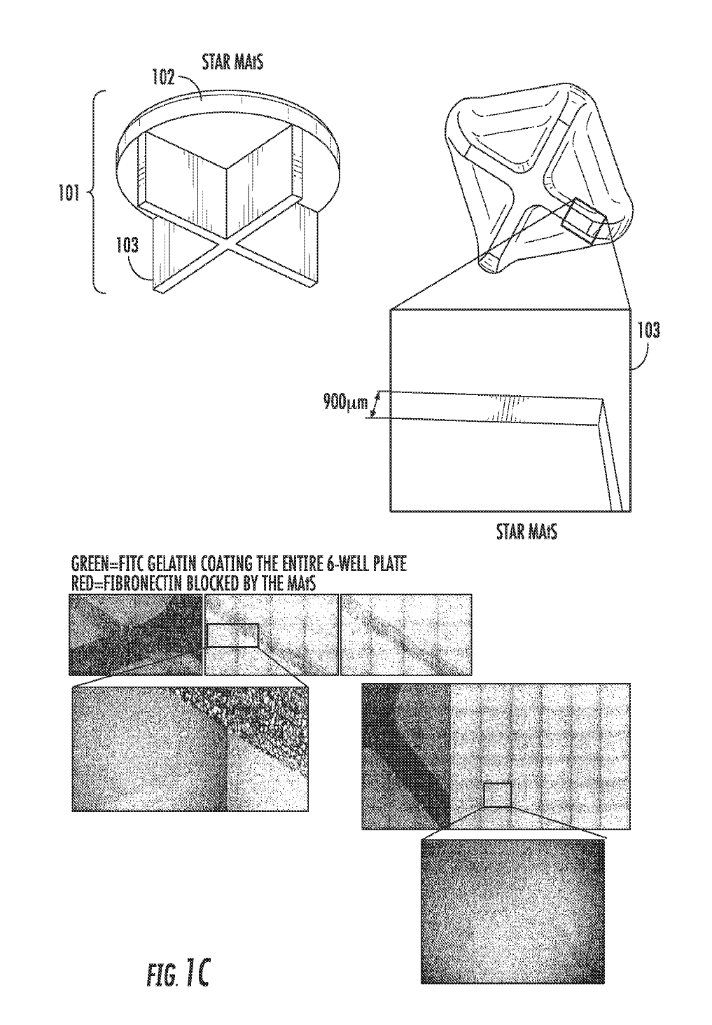

These have wide applicability in cellular assays, such as for example, cellular migration in 2 dimensions. One application of the MRAT, for example, comprises the patterning of cells and proteins on solid surfaces for the purpose of biological experimentation in vitro. Migration MRATs are readily applied to standard cell culture where, by occupying part of the culture surface, it creates an open space in the cell population, see, for example FIG. 1). Subsequent removal of the MRAT is followed by rapid migration of the cells into the open space. This space-filling model of migration is a very reproducible method for quantifying cell migration, FIG. 1A is an illustrative example of “Star MRAT”. In general, the MRAT can be fabricated in any size, shape, physical or chemical properties. In the so-called “star” shape, as shown in FIG. 1A, the stencil, 101, comprises a top or bottom element, 102, which can have varying shapes or diameters depending on the use. Thus, if the stencil is for a 96-well plate assay, the diameter would be adjusted to fit to a round well of the plate. The stencil also comprises one or more dividers or spacers, 103, of varying height and thickness. In some embodiments, the dividers are solid, rigid, flexible or porous.

In another preferred embodiment, the top or bottom element, 102, and the dividers or spacers, 103, can comprise different materials. For example, the dividers may comprise a material which can be suitably coated with one or more molecules, as desired by the user. These molecules can include, for example, polynucleotides, oligonucleotides, proteins, polypeptides, peptides, carbohydrates, organic or inorganic molecules. In another aspect, the element, 102, and the dividers, 103, comprise varying amounts of paramagnetic material. Embodiments comprising solid MRAT devices made of biocompatible material, such as for example, PDMS, comprise at least one magnetic or paramagnetic material. These devices can be made in any shape using microfabrication, milling, and molding techniques. These devices can be positioned and secured using magnetic forces. Element 102 may also comprise a protruding member, vertically attached to element 102, for ease of removing the stencil.

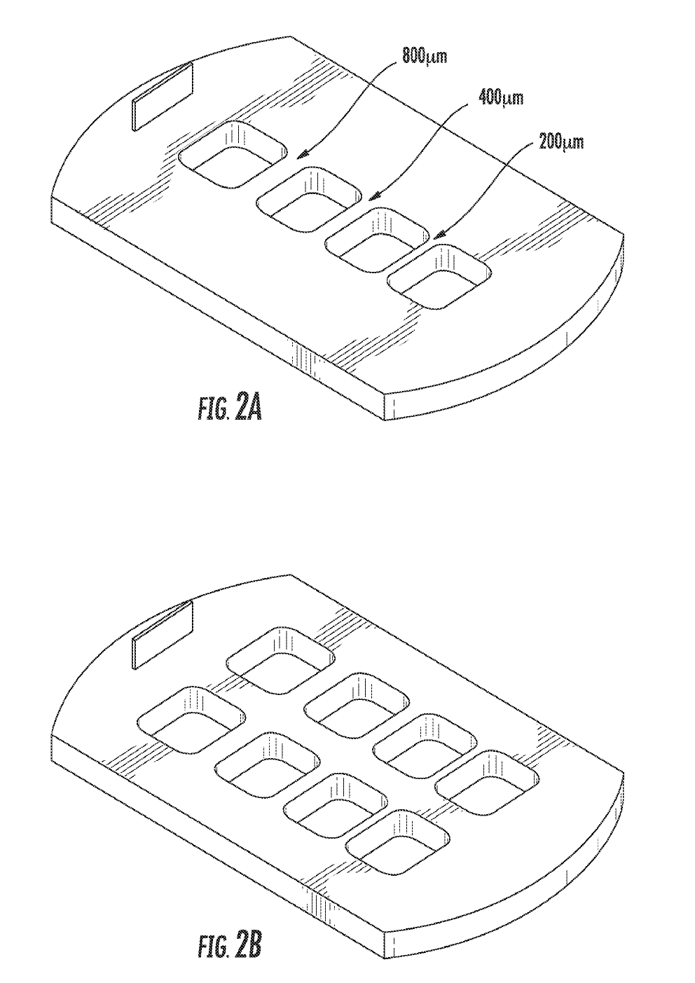

FIGS. 2A and 2B show an example of another embodiment of a MRAT. The stencil can be dimensioned in various sizes and shapes, depending on the end-users' application. In this illustrative example, the stencil is rectangular with rounded edges and is about 15 mm long and about 10 mm wide. The stencil comprises one or more wells which can vary in size and shape (FIG. 2B). The wells can be separated form each other by dividers comprising varying widths, in the illustrative example shown in FIG. 2A, the wells are separated by 800 μm, 400 μm and 200 μm.

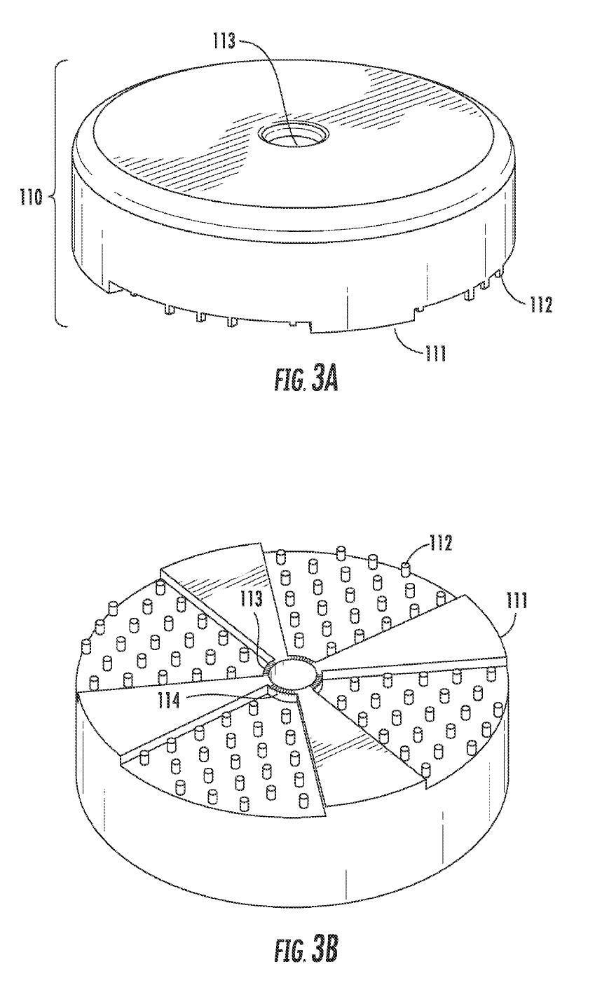

In another preferred embodiment, the MRAT comprises dividers and/or protruding members having various shapes, sizes, lengths, widths or combinations thereof. FIGS. 3A-3C is an illustrative example, showing a detachably attachable stencil, 110, used in a chemotaxis assay. In this illustrative example, the stencil is circular. The diameter of the stencil can vary so as to tit into conventional biological devices, such as for example, tissue culture dishes or plates, 96-well plates, 12-well plates, 6-well plates and the like. FIG. 3A shows a view of the stencil viewed from above. The figure shows the dividers, 111, and the protruding members, 112. FIG. 3B shows the stencil, 110, viewed from the bottom. The dividers, 111, and the protruding members, 112, are shown. FIG. 3C shows a close up view of the stencil, showing, in this embodiment, the micro-channels, 114, radiating from the center well, 113. The center well, 113, contains the test compound.

In another preferred embodiment, the dividers can be of varying thickness depending on the distance required to separate, for examples, the cells that are to be assayed.

In another preferred embodiment, the dividers are of any shape, thickness or size. For example, the dividers may be box shaped, or circular shape. The dimensions, shapes and the like are only limited by the user's imagination.

Compositions:

In a preferred embodiment, the MRAT (also termed “MAtS”) composition comprises: polydimethylsiloxane, polymethylmethacrylate, polyacrylic acid, polyacrylamide, polymethacrylamide, polyethacrylamide, polyalkacrylamides, polyamides, polyacrylonitrile, polybutadiene, polycaprolactone, polyethylene, polypropylene, polystyrene, polydivinylbenzene, polyethylene glycol, polypropylene glycol, polylactide, polyglycolide, polyornithine, polyvinyl acetate, polyvinyl alcohol, polyvinyl chloride, polyvinyl isobutyl ether, polyvinyl methyl ether, polyurethane, and polyvinylpyrrolidone, polymeric organosilicon, polytetrafluoroethylene, poly(p-xylylene) polymers, copolymers thereof, glass, rubber, ferrimagnetic, ferromagnetic, or paramagnetic particles.

In another preferred embodiment, the MRAT comprises compositions having elastomeric properties. However, the stencil need not be flexible, as in some cases a rigid unit may be preferred depending on the use. For example, a rigid stencil may be used in microfluidic devices, protein or nucleic acid chips. The polymeric materials are selected from elastomeric polymers such as silicones polysiloxanes and substituted polysiloxanes), polyurethanes, thermoplastic elastomers, ethylene vinyl acetate copolymers, polyolefin elastomers, and EPDM rubbers.

In another preferred embodiment, the MRAT is made of glass, plastics, metal, alloys, rubber, styrenes, and the like. The stencil, further comprises magnetic particles.

In one embodiment, the MRAT can comprise layers or coats of different materials. For example, the polymeric material in the first coating layer may be the same as or different than the polymeric material in the second coating layer. The thickness of the coating is not limited, but generally ranges from about 5 μm to about 0.5 mm. Preferably, the thickness is about 5 μm to 100 μm.

In general, synthetic polymers are preferred, although natural polymers may be used and have equivalent or even better properties, especially some of the natural biopolymers which degrade by hydrolysis, such as some of the polyhydroxyalkanoates. Representative synthetic polymers are: poly(hydroxy acids) such as poly(lactic acid), poly(glycolic acid), and poly(lactic acid-co-glycolic acid), poly(lactide), poly(glycolide), poly(lactide-co-glycolide), polyanhydrides, polyorthoesters, polyamides, polycarbonates, polyalkylenes such as polyethylene and polypropylene, polyalkylene glycols such as poly(ethylene glycol), polyalkylene oxides such as polyethylene oxide), polyalkylene terepthalates such as polyethylene terephthalate), polyvinyl alcohols, polyvinyl ethers, polyvinyl esters, polyvinyl halides such as polyvinyl chloride), polyvinylpyrrolidone, polysiloxanes, polyvinyl alcohols), polyvinyl acetate), polystyrene, polyurethanes and co-polymers thereof, derivativized celluloses such as alkyl cellulose, hydroxyalkyl celluloses, cellulose ethers, cellulose esters, nitro celluloses, methyl cellulose, ethyl cellulose, hydroxypropyl cellulose, hydroxy-propyl methyl cellulose, hydroxybutyl methyl cellulose, cellulose acetate, cellulose propionate, cellulose acetate butyrate, cellulose acetate phthalate, carboxylethyl cellulose, cellulose triacetate, and cellulose sulfate sodium salt (jointly referred to herein as “synthetic celluloses”), polymers of acrylic acid, methacrylic acid or copolymers or derivatives thereof including esters, poly(methyl methacrylate), poly(ethyl methacrylate), poly(butylmethacrylate), poly(isobutyl methacrylate), poly(hexylmethacrylate), poly(isodecyl methacrylate), poly(lauryl methacrylate), poly(phenyl methacrylate), poly(methyl acrylate), poly(isopropyl acrylate), poly(isobutyl acrylate), and poly(octadecyl acrylate) (jointly referred to herein as “polyacrylic acids”), poly(butyric acid), poly(valeric acid), and poly(lactide-co-caprolactone), copolymers and blends thereof. As used herein, “derivatives” include polymers having substitutions, additions of chemical groups and other modifications routinely made by those skilled in the art.

In one embodiment, a biodegradable polymer may be used to coat parts of the stencil forming the chambers and imprinted patters, and this coating may optionally comprise one or more compounds, which may also be encapsulated with these biodegradable polymers or other suitable encapsulating materials (e.g. a liposome) that are released over time into the experimental unit. For example, use in chemotaxis, modulation of cell receptors, and the like. Examples of preferred biodegradable polymers include polymers of hydroxy acids such as lactic acid and glycolic acid, and copolymers with PEG, polyanhydrides, poly(ortho)esters, polyurethanes, poly(butyric acid), poly(valeric acid), poly(lactide-co-caprolactone), blends and copolymers thereof.

Examples of preferred natural polymers include proteins such as albumin, collagen, gelatin and prolamines, for example, zein, and polysaccharides such as alginate, cellulose derivatives and polyhydroxyalkanoates, for example, polyhydroxybutyrate. The stability of the microparticles can be adjusted during the production by using polymers such as poly(lactide-co-glycolide) co-polymerized with polyethylene glycol (PEG).

In another preferred embodiment, the MRAT comprises one or more biocompatible materials. Examples include, but not limited to, polycarboxylic acids, cellulosic polymers, including cellulose acetate and cellulose nitrate, gelatin, polyvinylpyrrolidone, crosslinked polyvinylpyrrolidone, polyanhydrides including maleic anhydride polymers, polyamides, polyvinyl alcohols, copolymers of vinyl monomers such as EVA, polyvinyl ethers, polyvinyl aromatics, polyethylene oxides, glycosaminoglycans, polysaccharides, polyesters including polyethylene terephthalate, polyacrylamides, polyethers, polyether sulfone, polycarbonate, polyalkylenes including polypropylene, polyethylene and high molecular weight polyethylene, halogenated polyalkylenes including polytetrafluoroethylene, polyurethanes, polyorthoesters, proteins, polypeptides, silicones, siloxane polymers, polylactic acid, polyglycolic acid, polycaprolactone, polyhydroxybutyrate valerate, styrene-isobutylene copolymers and blends and copolymers thereof. Also, other examples of such polymers include polyurethane (BAYHDROL™, etc.) fibrin, collagen and derivatives thereof, polysaccharides such as celluloses, starches, dextrans, alginates and derivatives, hyaluronic acid, and squalene. Further examples of the polymeric materials used in the composition of the present invention include other polymers which can be used include ones that can be dissolved and cured or polymerized or polymers having relatively low melting points that can be blended with biologically active materials. Additional suitable polymers include, thermoplastic elastomers in general, polyolefins, polyisobutylene, ethylene-alphaolefin copolymers, acrylic polymers and copolymers, vinyl halide polymers and copolymers such as polyvinyl chloride, polyvinyl ethers such as polyvinyl methyl ether, polyvinylidene halides such as polyvinylidene fluoride and polyvinylidene chloride, polyacrylonitrile, polyvinyl ketones, polyvinyl aromatics such as polystyrene, polyvinyl esters such as polyvinyl acetate, copolymers of vinyl monomers, copolymers of vinyl monomers and olefins such as ethylene-methyl methacrylate copolymers, acrylonitrile-styrene copolymers, ABS (acrylonitrile-butadiene-styrene) resins, ethylene-vinyl acetate copolymers, polyamides such as Nylon 66 and polycaprolactone, alkyd resins, polycarbonates, polyoxymethylenes, polyimides, epoxy resins, rayon-triacetate, cellulose, cellulose acetate, cellulose butyrate, cellulose acetate butyrate, cellophane, cellulose nitrate, cellulose propionate, cellulose ethers, carboxymethyl cellulose, collagens, chitins, polylactic acid, polyglycolic acid, polylactic acid-polyethylene oxide copolymers, EPDM (ethylene-propylene-diene) rubbers, fluorosilicones, polyethylene glycol, polysaccharides, phospholipids, and combinations of the foregoing.

Paramagnetic and Non-Paramagnetic Materials:

In another preferred embodiment, the composition of the MRAT comprises magnetic particles. In a preferred embodiment, the magnetic particles comprise at least one of paramagnetic, ferromagnetic, anti-ferromagnetic or ferrimagnetic particles.

In the instant specification, the term “magnetic particles” means particles comprising a magnetic material. Magnetic materials include ferromagnetic substances, i.e., substances which exhibit good magnetic susceptibility, such as ferrous substance including iron oxide steel, stainless steel; paramagnetic substances, such as aluminum, which have unpaired electrons and are attracted into a magnetic field; diamagnetic substances, such as gold, wherein all electrons are paired and are slightly repelled by the electromagnetic field. Preferably, the magnetic particles used for the present invention comprise a ferrimagnetic or paramagnetic substance.

The magnetic particles of this invention preferably have paramagnetic properties. That is, the particles have atomic magnetic dipoles that align with an external magnetic field. Accordingly, the particles of this invention are attracted by magnets and can attract like normal magnets when subject to a magnetic field.

The paramagnetic material is constituted of very fine particles of mineral oxides with paramagnetic properties such as magnetite (a mixed iron oxide), hematite (an iron oxide), chromite (a salt of iron and chrome) and all other material attracted by a permanent magnet or electromagnet. Also ferrites such as iron tritetraoxide (Fe₃O₄), .gamma.-sesquioxide (γ-Fe₂O₃), MnZn-ferrite, NiZn-ferrite, YFe-gamet, GaFe-gamet, Ba-ferrite, and Sr-ferrite; metals such as iron, manganese, cobalt, nickel, and chromium; alloys of iron, manganese, cobalt, nickel, and the like, but not limited thereto, can be used. The preferred material is magnetite because of its availability and low cost, it is supplied as particles of different size, dry or as an aqueous stabilized suspension.

These particles are dispersed within the polymeric network and confer to the entire particle the property to be attracted by a permanent magnet or an electromagnet. The distance between the magnet and the stencils can be varied. See, the examples section which follows.

The non-paramagnetic material on which chemical structures are attached are made of polymeric materials. Preferred polymers have been described above. The following common polymeric materials are: crosslinked acrylates, polystyrene, polyurethane, polyvinyl, nylon, and polysaccharides. More specifically, these polymeric materials include organic polymers produced by polymerization of a polymerizable monomer: the monomer including styrenic polymerizable monomers such as styrene, α-methylstyrene, β-methylstyrene, o-methylstyrene, m-methylstyrene, p-methylstyrene, 2,4-dimethylstyrene, p-n-butylstyrene, p-t-butylstyrene, p-n-hexylstyrene, p-n-octylstyrene, p-n-nonylstyrene, p-n-decylstyrene, p-n-dodecylstyrene, p-methoxystyrene, and p-phenylstyrene; acrylic polymerizable monomers such as methyl acrylate, ethyl acrylate, n-propyl acrylate, isopropyl acrylate, n-butyl acrylate, isobutyl acrylate, t-butyl acrylate, n-amyl acrylate, n-hexyl acrylate, 2-ethylhexyl acrylate, n-octyl acrylate, n-nonyl acrylate, cyclohexyl acrylate, benzyl acrylate, dimethylphosphatoethyl acrylate, diethylphosphatoethyl acrylate, dibutylphosphatoethyl acrylate, and 2-benzoyloxyethyl acrylate; methacrylic polymerizable monomer such as methyl methacrylate, ethyl methacrylate, n-propyl methacrylate, isopropyl, methacrylate, n-butyl methacrylate, isobutyl methacrylate, t-butyl methacrylate, n-amyl methacrylate, n-hexyl methacrylate, 2-ethylhexyl methacrylate, n-octyl methacrylate, n-nonyl methacrylate, diethylphosphatoethyl methacrylate, acrylamide, methacrylamide and derivatives; dibutylphosphatoethyl methacrylate; methylene-aliphatic monocarboxylic acid esters; vinyl polymerizable monomer such as vinyl esters, vinyl acetate, vinyl propionate, vinyl benzoate, vinyl butyrate, vinyl benzoate, and vinyl formate; vinyl ethers such as vinyl methyl ether, vinyl ethyl ether, and vinyl isobutyl ether; and vinyl ketones such as vinyl methyl ketone, vinyl hexyl ketone, and vinyl isopropyl ketone. Other examples of the polymeric structures are those made of inorganic solids, including clay minerals such as kaolinite, bentonite, talc, and mica; metal oxides such as alumina, titanium dioxide, and zinc oxide; insoluble inorganic salts such as silica gel, hydroxyapatite, and calcium phosphate gel; metals such as gold, silver, platinum, and copper; and semiconductor compounds such as GaAs, GaP, and ZnS. The material is not limited thereto. The polymeric structure may be used in combination of two or more thereof.

The magnetic particles may be capsules made of non-magnetic substance, such as silica, encapsulating a magnetic substance or particles made of a mixture of a non-magnetic substance and a magnetic substance. Also, the magnetic particles may be coated with a polymeric material to reduce any undesirable effects that may be caused by the corrosive nature of the magnetic substance.

The average size of the particles is normally within the range from about 0.01 μm to about 10 μm. However, the average particle size may be any other suitable range such as from about 0.01 μm to about 50 μm. In preferred embodiments, the magnetic particles are less than about 5 μm. The sizes should be determined based on various factors including a thickness of the stencil and the dimensions of the fine features.

The concentration of the magnetic particles in a composition of the stencil should be determined based on various factors including the size of the particles and desired strength of the magnetic force, etc. Normally, the concentration of the magnetic particles ranges from about 2% to about 50% by weight. Preferably, the range is about 20% to about 35%. The compositions and methods of manufacturing the stencil are described in detail in the examples section which follows. The following provides a general overview for dispersing the magnetic particles.

The magnetic particles may be dispersed by any of the well-known methods, including grinding, milling, and ultrasonic techniques. For example, magnetic particles in the form of a fine powder are added to the suspending solvent and the resulting mixture is ball milled or attrited for several hours to break up the highly agglomerated dry pigment powder into primary particles. Low vapor pressure, non-hygroscopic solvents are preferred for the magnetophoretic or electromagnetophoretic fluid. Examples of useful solvents include, but not limited to, hydrocarbons such as decahydronaphthalene (DECALIN), 5-ethylidene-2-norbornene, fatty oils, paraffin oil, aromatic hydrocarbons such as toluene, xylene, phenylxylylethane, dodecylbenzene and alkylnaphthalene, low viscosity polyethers such as polypropylene glycols and block copolymers of ethylene glycol and propylene glycols, low viscosity silicone oils, alkyl or alkylaryl esters and ketones, halogenated solvents such as perfluorodecalin, perfluorotoluene, perfluoroxylene, dichlorobenzotrifluoride, 3,4,5-trichlorobenzotrifluoride, chloropentafluoro-benzene, dichlorononane and pentachlorobenzene, perfluoro solvents such as FC-43, FC-70 and FC-5060 from 3M Company, St. Paul Minn., low molecular weight halogen containing polymers such as poly(perfluoropropylene oxide) from TCI America, Portland, Oreg., poly(chlorotrifluoroethylene) such as Halocarbon Oils from Halocarbon Product Corp., River Edge, N.J. and perfluoropolyalkylether such as Galden from Ausimont or Krytox Oils and Greases K-Fluid Series from DuPont, Del. Poly(chlorotrifluoroethylene) and poly(perfluoropropylene oxide) can be used as a dielectric solvents.

Magnetic particles prepared from highly magnetic compounds and metals or alloys are preferred. Examples of magnetic materials useful in this invention include, but not limited to, gamma ferric oxide, acicular magnetite, cobalt-modified or adsorbed ferric oxide, berthollide ferric oxide, chromium dioxide, metals or alloys such as stainless steel, Fe—Co, Co—Ni, Co—Cr and Fe—Co—V alloys, organic polyradicals such as polymers with organic radicals in the side chain, main-chain conjugated polymers with organic radicals, two dimensional polyradicals, polymers containing paramagnetic metalloporphyrins as side chains and polymers containing paramagnetic metal ions, e.g., Cu(II), Ni(II), Mn(II) or VO(II), in the main chain. Other useful magnetic materials can be found in references such as “Magnetic Recording Handbook” by Marvin Camras; Van Norstrand Reinhold Co., (1.988); and M. Kamachi “Magnetic Polymers” in“Functional Monomers and Polymers”, ed. By K. Takemoto, R. M. Ottenbrite and M. Kamachi; Marcel Dekker, Inc., (1997).

In a preferred embodiment, the polymers comprise paramagnetic or ferrimagnetic particles.

In one embodiment, the MRAT comprises small beaded material having paramagnetic properties. Particles with paramagnetic properties useful for this invention are available from several commercial suppliers. These include, for example, Dynal (Invitrogen) (Carlsbad, Calif.), Ademtech (Pessac France—superparamagnetic nanoparticles) and Spherotech (Libertyville, Ill.). These can be particularly useful in microchip patterning of nucleic acids or peptides. Small beaded materials with paramagnetic properties of the present invention can be made using several methods.

Coating Compositions:

In some embodiments, the stencil may comprise a coating which allows for the release of a test compound into the experimental unit. Examples of methods to coat a stencil are, for example, painting, spraying, dipping, rolling, electrostatic deposition and all modern chemical ways of immobilization of bio-molecules to surfaces.

The coating composition may be a solution or a suspension of a polymeric material and/or a biologically active material and/or magnetic particles in an aqueous or organic solvent suitable for the medical device which is known to the skilled artisan. A slurry, wherein the solid portion of the suspension is comparatively large, can also be used as a coating composition. Such coating composition may be applied to a surface, and the solvent may be evaporated, and optionally heat or ultraviolet (UV) cured.

The solvents used to prepare coating compositions include ones which can dissolve the polymeric material into solution and do not alter or adversely impact the therapeutic properties of the biologically active material employed. For example, useful solvents for silicone include tetrahydrofuran (THF), chloroform, toluene, acetone, isooctane, 1,1,1-trichloroethane, dichloromethane, and mixture thereof.

A coating may consist of various combinations of coating layers. For example, the first layer disposed over the surface of the stencil can contain a polymeric material and a first biologically active material. The second coating layer, that is disposed over the first coating layer, contains magnetic particles and optionally a polymeric material. The second coating layer protects the compound or biologically active material to be tested, in the first coating layer and can be of varying thickness to protect the compound or biologically active material prior to the experiment. The coating can further be made of polymers which degrade over specified times. For example, microparticles can be designed to release molecules over a period of minutes, hours, days to weeks. Such materials are known in the art. For example, aliphatic polyesters differ in hydrophobicity and that in turn affects the degradation rate. Specifically the hydrophobic poly(lactic acid) (PLA), more hydrophilic poly(glycolic acid) PGA and their copolymers, poly(lactide-co-glycolide) (PLGA) have various release rates. The degradation rate of these polymers, and often the corresponding drug release rate, can vary from days (PGA) to months (PLA) and is easily manipulated by varying the ratio of PLA to PGA.

Patterns:

The examples section which follows, provides details on the manufacture of the stencils having different patterns, chambers, channels, protrusions etc. The master template, as describe serves as the master template which contains the desired pattern obtained by, for example, photolithography. The patterns or chamber designs, shapes sizes, etc are limited only by a user's imagination. Some examples include, creating void spaces in cell culture monolayers; creating a micro well to culture cells (when place on standard culture surfaces); creating a 3D culture space for chemotaxis and invasion (when place on standard culture surfaces); creating a fluid barrier for retaining and isolating liquid around an object and the like.

In another preferred embodiment, a MRAT can be imprinted with, for example, proteins, using a variety of techniques, such as liquid deposition. The phrases “liquid deposition technique” or “liquid depositing” refer to, for example, the deposition of a composition using a liquid process such as liquid coating or printing, where the liquid is a solution or a dispersion. Examples of liquid coating processes may include, for example, spin coating, blade coating, rod coating, dip coating, and the like.

In another preferred embodiment, the MRAT comprise a detachable template for microscale casting, molding, and photolithography. In some embodiments, features are added to the mold after it is created. These features can be added to the stencils so as to meet various technical requirements of engineering a cellular microenvironment. For example, stencils can serve as selective physical barriers, and may allow a substrate to be patterned with features of virtually any size or shape. The stencil may be engineered to have various surface properties. The surface properties may be produced by a surface treatment applied during manufacturing of the stencil, or a surface treatment may be applied after manufacturing. In addition, a surface treatment may be applied during processing or use (i.e. during an experiment). Alternatively, the stencil may be produced and used without a surface treatment.

In another preferred embodiment, the stencil comprises 3-dimensional (3D) topography on PDMS for simultaneous 2D photolithography and 3D patterning of photoresists.

in another preferred embodiment, a MRAT is a three-dimension cell invasion device. MRAT constructed for chemotaxis can also be used for analyzing invasion. The same principle design is used. In one embodiment, the device is filled with a solid matrix and the MRAT are “open faced”. Most microfabricated devices are “closed” to ensure proper sealing of all the internal chambers and channels. Since MAtS are reversibly sealed with magnets, the device is fined in some embodiments, with a solid or with a polymerizing liquid such as, for example, collagen and matrigel.

In one embodiment, a device for assaying, for example, cell invasion, MRATs are directly applied to a culture surface which is covered with a layer of extracellular matrix. In other embodiments, the matrix is applied to the MRAT prior to placing it onto the culture surface. For example, the cells are subsequently resuspended in the same extracellular matrix and applied to the culture surface adjacent to the MRAT. The central well is subsequently filled with a chemotactic agent which diffuses towards the cultured cells. These cells subsequently invade the matrix filled device.

In addition to the benefits described above, this device provides a mechanism to study directional invasion. The fact that there is a defined start point and a defined direction of invasion greatly improves analysis and quantitation of the data.

In another preferred embodiment, the patterned stencil may form a co-pattern with multiple proteins which can be printed onto the stencil.

In another preferred embodiment, the device comprises a detachable template for microscale casting, molding, and photolithography. In one preferred embodiment, the one or more 2-dimensional and/or 3-dimensional features are added to the mold. For example, dimensional topography on PDMS MRAT for simultaneous 2D photolithography and 31) patterning. In another preferred embodiment, the MRATs comprise a large device. In one embodiment, the manufacture of large MRATs devices and structures comprises using a microfluidic master for example. The process method comprises a master plate, mold, the stencils (e.g. MRATs), magnets, a microfluidic master plate, which can be coated with a thin coating of material, for example, a polyvinyl alcohol. This coating is applied to the microfluidic master plate. The MRATs are attached to the master plate by the magnets, thus, patterning is also obtained by the pattern of magnets. The MRATs can be of any shape, size or design that is desired by the user. The coating material is washed away. The microfluidic device can then be cast by pouring in a material such as for example, epoxy, curing and removal of the stencils by detaching the magnets.

In another preferred embodiment, a multilayer MRAT may be used for patterning proteins. As an example, after protein coating, the top layer of the stencil may be removed, leaving a precise protein pattern. The initial protein patterning may fully coat the bottom of the microwells formed by the stencil, making it resistant to further protein deposition. Accordingly, this enables co-patterns of proteins to be formed without deposition of the co-patterned proteins in the microwells. The initial protein pattern will remain stable and retain integrity as additional layers are peeled away, as the microwells fully retain their position and location on the substrate surface as the additional layers are removed. Protein deposition patterns can also easily be varied by changing the geometry of the stencil. The technology further allows for the generation of dynamic co-patterns of multiple proteins. Selective patterning of proteins such as antibodies and enzymes, for example, has recently attracted much interest for the study of specific protein-protein interactions and the development of diagnostic kits, protein sensors, and protein chips.

In another preferred embodiment, the patterned MRATs can be utilized in both micro and macro applications.

Other various means may also be used to define such channels or chambers in the stencil. For example, a computer-controlled plotter modified to accept a cutting blade may be used to cut various patterns through a material layer. Such a blade may be used either to cut sections to be detached and removed from the stencil, or to fashion slits that separate regions in the stencil without removing any material. Alternatively, a computer-controlled laser cutter may be used to cut portions through a material layer. While laser cutting may be used to yield precisely-dimensioned microstructures, the use of a laser to cut a stencil layer inherently involves the removal of some material. Further examples of methods that may be employed to form stencil include conventional stamping or die-cutting technologies, including rotary cutters and other high-throughput auto-aligning equipment (sometimes referred to as converters). The above-mentioned methods for cutting through a stencil layer or sheet permits robust devices to be fabricated quickly and inexpensively to produce microfluidic devices.

The thickness or height of the microstructures such as channels or chambers can be varied by altering the thickness of the stencil layer, or by using multiple substantially identical stencil layers stacked on top of one another. When assembled in a microfluidic device, the top and bottom surfaces of stencil layers are intended to mate with one or more adjacent layers (such as stencil layers or substrate layers) to form a substantially enclosed device, typically having at least one inlet port and at least one outlet port. A wide variety of materials may be used to fabricate microfluidic devices having sandwiched stencil layers, including polymeric, metallic, and/or composite materials, to name a few. In certain embodiments, particularly preferable materials include those that are substantially optically transmissive to permit viewing and/or electromagnetic analyses of fluid contents within a microfluidic device. Various preferred embodiments utilize porous materials including filter materials. Substrates and stencils may be substantially rigid or flexible. Selection of particular materials for a desired application depends on numerous factors including: the types, concentrations, and residence times of substances (e.g., solvents, reactants, and products) present in regions of a device; temperature; pressure; pH; presence or absence of gases; and optical properties.

Since the MRATs are magnetically attachable and detachable, adhesives and other materials are not required. However, if desired by the user, attachment techniques including thermal, chemical, or light-activated bonding steps; mechanical attachment (such as using clamps or screws to apply pressure to the layers); and/or other equivalent coupling methods may be used.

Notably, MRAT-based fabrication methods enable very rapid fabrication of devices, both for prototyping and for high-volume production. Rapid prototyping is invaluable for trying and optimizing new device designs, since designs may be quickly implemented, tested, and (if necessary) modified and further tested to achieve a desired result. The ability to prototype devices quickly with stencil fabrication methods also permits many different variants of a particular design to be tested and evaluated concurrently. Further embodiments may be fabricated from various materials using well-known techniques such as embossing, stamping, molding, and soft lithography.

In preferred embodiments, the MRAT is dimensioned or molded so as to be incorporated in a standard biological device or culture unit, e.g. 128-well plates, 96-well plates, 6 well plates, tissue culture dishes, plates, and the like. Other examples, include, high-throughput screening components, tubes, culture bottles, tubes and the like. Shapes, sizes, components, clear or colored, compositions are only limited by the imagination of the user. Since the MRAT composition comprises magnetic particles, the MRAT is reversibly attached to the device of choice. The MRAT is attachable when it is subjected to a magnetic force, and it is detachable when the magnetic force is removed, e.g. electro-magnet, or removal of the standard magnet. In some embodiments the biological device may be placed on an electro-magnet to control the strength and timing of the magnetic force.

In another preferred embodiment, the distance between the MRAT/MAtS and the magnets are varied. The distance between the magnet and the material used for the magnetic force can be varied so as to vary the magnetic forces. These can be changed during the course of the desired assay. One of skill in the art would be able to vary the strength of the magnetic forces, such as for example, using electromagnets, different materials having varied magnetic properties, varying concentrations of the magnetic materials, different magnets, etc.

As shown in the illustrations, e.g. FIGS. 1-3C, the MRAT comprises a patterned surface having a plurality of shapes, sizes, base elements, top elements, protrusions, recesses, dividers, microchannels, or combinations thereof. When the MRAT is reversibly attached to the biological device or culture unit, the MRAT forms the desired imprinted pattern or chamber for analyzing biological samples, separating and patterning cells and molecules. For example, FIGS. 3A-3C show one of the many embodiments of the MRAT which can be used to analyze, for example, chemotaxis. When the MRAT is attached to the biological device, the cells are separated by the dividers 111 and a chamber is thus, formed comprising: void spaces, micro wells, three-dimensional culture spaces, fluid barriers, movable flaps, porous dividers, microfluidic channels, micro-printed patterns, or combinations thereof. The dividers may comprise microchannels to allow a compound to diffuse or allow “cross-talk” between cells in different chamber, etc. As shown in FIG. 3A, in this embodiment, the dividers extend from a first opposing face of two opposing faces from a central axis of a main plate to a peripheral edge thereof. The width of the dividers can be of any thickness, and are at least about 0.01 μm wide. In addition to the dividers, the stencil may comprise protruding elements,

### Applications

The benefits of MRATs over other applications have been described above. These include: MRATs can be applied to wet, protein-coated surfaces (which are the norm in biological systems) because they do not need chemical or auto-adhesive bonding to the surface, MRATs are held in place by magnets which ensure that a uniform, consistent force is applied each time the MRATs are used. This greatly reduces error introduced by the user, MRATs do not disrupt the matrix on which they are placed. This allows for the analysis of migration on defined matrix using a space-filling model. This has not, heretofore, been possible with existing techniques. MRATs do not require a mechanical compression force which eliminates the need for clamps or other compression devices. This greatly improves access to the cell culture being examined. MRATs can be applied to all cell culture systems currently in use. No specialized culture vessel needs to be adapted for use of the stencil. MRATs can be created in any desired shape. Two basic designs of MRATs are currently in used for the space filling model: 1) a micro-well MRAT in which small populations of cells are cultured side-by-side and separated by a 100-800 μm barrier (see, for example, FIG. 2). 2) across-shaped MRAT which is placed inside a small culture vessel (such as a 6-well plate) and cells are cultured around the device (see, for example, FIG. 1). The uses of these MAtS systems are only limited by the imagination of the user. The examples below are given merely to illustrate the variety of uses or applications and are not to be construed as limiting in any way.

Chemotaxis in 2 Dimensional (“Chemataxis and Invasion” MRATs):

MRATs can be constructed to support passive diffusion based gradients of soluble reagents within fields of migrating cells. See, for example, FIGS. 3A-3C. A central well is created inside the MRAT which contains a chemotactic agent (promotes migration of cells towards the source of the agent). The chemotactic agent is allowed to diffuse into the open space (into which the cells can migrate). The use of a wedge-shaped migration space (with the narrow end at the chemotactic wells and the wide end facing the incoming cells) causes the formation of a chemotactic gradient.

Chemotaxis MRATs are directly applied to a culture surface which is covered with fluid (culture medium). The MRATs is held into place with a magnet and retained there for the duration of the experiment. Cells are subsequently added to the culture surface surrounding the device. The chemotactic reagent is added to the central well. The chemotactic reagent diffuses from the central well to the culture surface containing the cells. This causes the cells to migrate into the device. The chemotactic response is measured as the distance and the number of cells that migrated towards the chemotactic source.

Advantageously, the present invention can be used to measure or obtain data with respect to one or more parameters regarding the behavior of the cells and tissue. Those parameters include one or more of the distance which individual cells migrate, the average distance of migration of a group or population of cells; the distance which individual cells migrate with respect to time; the average distance of migration of a group or population of the cells with respect to time, the velocity of migration of one or more designated individual cells per selected time period; the velocity of migration of a group or population of designated cells per selected time period; the number of migrating cells per unit area of a chamber; the speed of proliferation of the cells; the number of directional changes per unit time of the migrating cells; the rate of mitosis of the migrating cells; the number of cells migrating per unit time; the proportion of cells which change the direction of migration during the test period; the density of migrating cells per defined unit area; the distance of migration for individual migrating cells per unit area; the average distance migrated by a group or population of migrating cells per unit area.

The Benefits of Chemotaxis MRATs:

These devices are created as a single unit and require no assembly or additional components (other than a magnet to hold them in place). These devices are scalable and can be applied to a variety of standard cell culture vessels. The design of the device causes the physical separation between the cells and the chemotactic agent. This eliminates the need for separate means to contain the cells and create the gradient.

Invasion Assay in 3 Dimensions (“Chemotaxis and Invasion” MRATs):

MRATs constructed for chemotaxis can also be used for analyzing invasion. The same principle design is used. Instead of filling the device with fluid, the device is filled with a solid matrix. This is possible because the MRATs are “open faced”. Most microfabricated devices are “closed” to ensure proper sealing of all the internal chambers and channels. Since MRATs are reversibly sealed with magnets, it is possible to fill the device with a solid or with a polymerizing liquid such as collagen and matrigel.

Invasion MRATs are directly applied to a culture surface which is covered with a layer of extracellular matrix. Alternatively the matrix can be applied to the MRATs prior to placing it onto the culture surface. The cells are subsequently resuspended in the same extracellular matrix and applied to the culture surface adjacent to the MRATs. The central well is subsequently filled with a chemotactic agent which diffuses towards the cultured cells. These cells will subsequently invade the matrix filled device.

In addition to the benefits described above, this device provides a mechanism to study directional invasion. The l′ act that there is a defined start point and a defined direction of invasion greatly improves analysis and quantitation of the data.

Cell Migration:

Cell migration is a multifactorial process that arises from multiple inputs. These inputs can be categorized into four broad categories: 1) matrix-related properties such as matrix proteins and elasticity; 2) cell autonomous characteristics such as genetic, epigenetic and protein expression; 3) soluble factors such as metabolites, stimulators and inhibitors; 4) cell-to-cell interaction and communication like cell adhesion molecules and cell-cell junctions. These many inputs are integrated by the cell and determine migration. This multifactorial integration has prior to now, been impossible to evaluate the contribution of any single factor except within the context of many other factors. Controlling and accounting for these multiple parameters is the primary challenge of all studies of cell migration.

Because cell migration is highly context dependent, the method or model chosen can significantly affect the outcome. In order to account for all 4 input categories, many methods have been created to study cell migration. For example, the traditional scratch assay analyzes cell migration as it results from cells with distinct cellular properties, with cell-cell interactions, and in specific solutions. Incorporating matrix conditions into scratch assays is tenuous at best. For this reason single cell migration is the usual approach for studying the impact of matrix conditions on migration. In the examples section which follows it is demonstrated how magnetically attachable stencils (MAtS) fill this need in cell migration methodologies by allowing control of all 4 categories.

Of the many methods for studying collective cell migration, the scratch assay is by far the most common. Yet the scratch assay is not without its limitations as seen by the many variations to it. Different tools have been employed to scratch away the cells such as steel pins, TEFLON wedge tips, even silicone tipped drill presses. One of the methods uses electricity to create the void after which the electrodes measure cell migration via impedance which changes as the cells cover the void.

Rather than removing cells from the substrate, several methods block cells from adhering. The advantage of all cell blocking methods is the maintenance of a virgin substrate. The most established of these techniques is the stopper. Stoppers wedge against the sides of specific multi-well plates and thus generate force between the tip which patterns the cells and the substrate. Silicone stoppers are commercially available. The major limitations of stoppers are the variability of the force between the tip and substrate and the restriction to using specific plates. A less restrictive method of blocking cells is the membrane stencil. Stencils rely on self-adhesion of a silicone or parylene material to seal against the substrate and successfully block cells. The limitation of stencils is that self-adhesive forces cannot be generated on wet custom-coated substrates.

Another approach is to use a gel as a barricade to block cells. After cells have adhered to the substrate, the gel dissolves or is dissolved by adding a reagent. Current cell blocking techniques such as stoppers, stencils, and gels, enable collective migration to occur on a virgin substrate but have not been shown compatible with custom-coated, wet substrates.

In order to fulfill such an unmet need the importance of the custom-built substrates for the study of the multifactorial process directing cell migration, the magnetically attachable stencil (MAtS) can be applied to a variety of custom-coated surfaces. In the examples which follow, the application of these novel magnetic stencils is demonstrated in collective cell migration highlighting the multifactorial nature of migration. First, the requirements essential to successfully patterning invasive cells are demonstrated on the custom substrates which also show the resulting cell monolayers. Next, the maintenance of the custom substrate was verified by fluorescent microscopy followed by analysis of migration on custom substrates and the interaction of the substrate conditions with i) epithelial-like A549 and mesenchymal-like HEp3 cell lines, ii) protein expression within murine mammary carcinoma cells, and iii) an antibody against CD-151 which inhibits migration in vitro and metastasis in vivo. Finally, the unprecedented patterning of collective cell monolayers was demonstrated on polyacrylamide substrates and the collective cell migration that occurs in response to a rigid or flexible substrate.

Additional Applications:

Examples include, but not limited to: open-face microfluidic systems; detachable fluid barrier on non-adherent surfaces; protein printing applications; mechanical valve. These stencils can be tailor made for application to a broad range of uses and fields of study, such as to pattern cells, manipulate fluids, transfer proteins via contact printing etc.

Examples of fields of study include, for example, cell biology-cell migration studies; importance of specific proteins in collective cell migration (for example matrix proteins like fibronectin or cell-cell adhesion molecules); chemotaxis studies; cell invasion studies; cell patterning and co-culture studies. Other fields include, microfluidics; microchip arrays, immunoassays, identification of novel therapeutics, gene or protein analysis, etc.

Data Analysis:

As another advantage, the data obtained by the measurements of the invention is recorded in a fixed communications media. Such fixed media can be any type so long as it is capable of holding the obtained data in such form as to be useable later. For example paper, voice recordings, video recordings, photographs, photomicrographs, digital recordings, any fixed digital data means, any computer network-facilitated means, infrared recording, ultrasound recordings, and magnetic resonance recordings. According to the invention one or more of a human observer, a still camera, a video camera, an automated still camera, an automated video camera, an infrared camera, and an automated infrared camera.

The components of the system may be interconnected via any suitable means including over a network, to the processor or computing device. The processor may take the form of a portable processing device that may be carried by an individual user e.g. laptop computer, and data can be transmitted to or received from any device, such as for example, server, laptop, desktop, PDA, cell phone capable of receiving data, BLACKBERRY™, and the like. In some embodiments of the invention, the system and the processor may be integrated into a single unit. In another example, a wireless device can be used to receive an image and forward it to another processor over a telecommunications network, for example, a text or multi-media message.

The functions of the processor need not be carried out on a single processing device. They may, instead be distributed among a plurality of processors, which may be interconnected over a network. Further, the information can be encoded using encryption methods, e.g. SSL, prior to transmitting over a network or remote user. The information required for decoding the captured encoded images taken from test objects may be stored in databases that are accessible to various users over the same or a different network.

In some embodiments, the data is saved to a data storage device and can be accessed through a web site. Authorized users can log onto the web site, upload scanned images, and immediately receive results on their browser. Results can also be stored in a database for future reviews.

In some embodiments, a web-based service may be implemented using standards for interface and data representation, such as SOAP and XML, to enable third parties to connect their information services and software to the data. This approach would enable seamless data request/response flow among diverse platforms and software applications.

In some embodiments, the data processor may implement an analysis program and/or functionality of the methods of the present invention as software on a general purpose computer. In addition, such a program may set aside portions of a computer's random access memory to provide control logic that affects the analysis programs etc. In such an embodiment, the program may be written in any one of a number of high-level languages, such as JAVA, FORTRAN, PASCAL, C, C++, or BASIC. Further, the program may be written in a script, macro, or functionality embedded in commercially available software, such as MATLAB, EXCEL or VISUAL BASIC. Additionally, the software could be implemented in an assembly language directed to a microprocessor resident on a computer. For example, the software could be implemented in Intel 80×86 assembly language if it were configured to run on an. IBM PC or PC clone. The software may be embedded on an article of manufacture including, but not limited to, computer usable medium such as a hard drive device, a CD-ROM, a DVD-ROM, or a computer diskette, having computer readable program code segments stored thereon.

It will be apparent to those of ordinary skill in the art that methods involved in the system and method for analysis of the data obtained from the various uses of the system, may be embodied in a computer program product that includes a computer usable medium. For example, such a computer usable medium can include a readable memory device, such as, a hard drive device, a CD-ROM, a DVD-ROM, or a computer diskette, having computer readable program code segments stored thereon. The computer readable medium can also include a communications or transmission medium, such as, a bus or a communications link, either optical, wired, or wireless having program code segments carried thereon as digital or analog data signals.

White various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments.

Alt documents mentioned herein are incorporated herein by reference. All publications and patent documents cited in this application are incorporated by reference for all purposes to the same extent as if each individual publication or patent document were so individually denoted. By their citation of various references in this document, Applicants do not admit any particular reference is “prior art” to their invention. Embodiments of inventive compositions and methods are illustrated in the following examples.

### EXAMPLES

The following non-limiting Examples serve to illustrate selected embodiments of the invention. It will be appreciated that variations in proportions and alternatives in elements of the components shown will be apparent to those skilled in the art and are within the scope of embodiments of the present invention.

### Example 1

### Magnetic Reversibly Attached Template (MRAT)

Elastomer formulation. Polydimethylsiloxane (PDMS) is made from the Sylgard 184 Silicone Elastomer Kit (Dow Corning). PDMS prepolymer is made by mixing 10 parts base to 1 part curing agent by weight as recommended by the manufacturer (though the ratio can vary significantly to produce more or less crosslinking resulting in stiffer or softer elastomers). This PDMS prepolymer may be degased at this point by vacuum or centrifugation and used as is. However, in most of the applications magnetite powder (iron(II, III) oxide, <5 μm particle size, Sigma-Aldrich, 310069) is mixed into the PDMS prepolymer at a ratio of 2 parts prepolymer to 1 part magnetite by weight which results in a mixture that is 33.3% magnetite by weight. When cured the PDMS-magnetite mixture (PDMS-M) is noticeably stiffer than plain PDMS. Plain PDMS made at the recommended 10:1 ratio has a Young's modulus (elastic modulus) of roughly 750,000 Pa. PDMS mixed with magnetite is noticeably stiffer. Nanoparticles of magnetite are superparamagnetic; however, based on the <5 μm rating of the magnetite used the vast majority of these particles are ferrimagnetic. The advantage of having ferrimagnetic or superparamagnetic particles rather than ferromagnetic materials is less hysteresis. Fern magnetic materials like ferromagnetic materials can hold a magnetic alignment. When the PDMS-M was cured in the presence of magnetic field, there was an increase in attraction between the PDMS-M device and a magnet.

Other.

Nitex mesh (≦310 micron opening, 45% open area) may be added as a flexible handle for removal of the device. Nitex mesh may also be embedded in the PDMS-M before curing, or PDMS-M may be cast over the nitex mesh. The mesh reinforces the PDMS-M, making the PDMS-M stronger.

### Design and Dimensions:

Microwell MRAT:

15 mm long, 10 mm wide, 2 mm tall. Each of the 4 wells is 2.5×3 mm. Spacing between the 4 wells is currently 800 μm, 400 μm, and 200 μm; however, a newer design has 700 μm spacing between all the wells.

Star MRAT:

10 mm diameter, 4 arms 4 mm long. The contact surface of each arm is 900 μm or 700 μm wide depending on the fabrication process. Having 700 microns between the cell monolayers is more suitable for imaging on standard 10× objectives than 900 μm which may not be completely visible.

Dot MRAT:

1.5 mm diameter or bottom contact surface, 5 mm tall, 1.7 mm diameter of top. Suitable for high-throughput in 96-well plates. Buoyancy can be added to the top of these MRATs to enable automated alignment and attachment of dot MRATs using fluid such as PBS or cell culture media and magnetic force.

Chemotaxis/Invasion MRAT:

20 mm diameter, 4 mm tall. The posts are 500 μm tall, and the height of the microchannels is 50 μm.

### Production and Assembly

Master molds were made by milling or photolithography. Computer numerical control milling can create positive reliefs of the desired MRATs. However, milling leaves toolmarks and is limited in resolution to one or two hundreds of micrometers. Photolithography enables the production of microscale size features. SU-8 (MicroChem) is a photoresist that can be formulated in a wide range of viscosities and crosslinks upon exposure to UV light thereby becoming an insoluble solid. Desired heights of SU-8 are created on silicon wafers or glass slides by spinning a certain formulation, for example, SU-8 2050, at a specified RPM. The desired pattern is applied to the film of SU-8 by placing a mask or stencil over the SU-8 and then exposing it to UV light for a specified amount of time at a given intensity. The 3-D structures are then “developed” by removing the unexposed SU-8 in a special solvent (SU-8 Developer, MicroChem).

Devices can be generally created by pouring PDMS or PDMS-M over the SU-8 features on the master. The PDMS or PDMS-M is cured for at least 2 hours at 70° C. (longer for lower temperatures). Then the PDMS or PDMS-M is cut and pealed away from the glass slide or silicon wafer. After the MRAT is removed from the master (the glass slide or silicon wafer patterned with SU-8) holes can be punched to create reservoirs or connections to fluidic channels and the final shape is achieved.

Creating a Crystal Clear Negative Mold:

After fabricating initial MRATs from SU-8 masters or by milling, a transparent polyurethane resin (Crystal Clear, Smooth-On) is used to make molds of multiple MRATs for high-throughput fabrication. The two parts of the Crystal Clear resin are mixed at a 100 to 90 ratio by weight according to the manufacturer's instructions. The resin is degased in high vacuum and then poured into a suitable container. Positive reliefs of MRATs are coated with a thin film of polyvinyl alcohol (PVA, Partall Film #10, RexCo) which acts both as a barrier and release agent and is water-soluble. The Crystal Clear is then poured over the milled relief or poured into a container. The MRATs from SU-8 masters are placed into the Crystal Clear in the container and removed after the Crystal Clear is cured. The Crystal Clear is cured at room temperature for about 24 hours and then baked for 2-4 hours at 70° F.

Casting the Devices.

After creating Crystal Clear molds, multiple devices are cast simultaneously greatly enhancing production quantities and avoiding damage to SU-8 masters.

Buoyancy:

Adding buoyancy to the MRAT facilitates attachment and removal of the MRAT. Adding buoyancy to the top end of dot MAtS enables MRATs to be aligned and attached by controlling the distance between the magnets and MRATs and the volume of cell culture media or PBS in the wells of a multi-well plate. After removing the underlying magnets, MRATs can float to the surface of the fluid. Currently, MRATs are removed manually with broad-tipped tweezers or by bringing a magnet or electromagnet from above into proximity with each MRAT. The Star MRAT design can be removed utilizing not only its inherent buoyancy but also its hydrophobicity. Filling the wells of a 6-well plate with 5-6 ml of medium or PBS creates a meniscus bulging upward around the magnetically attached templates. When the magnets are removed from under the stencils, the surface tension pulls the MRAT upward where they can easily be removed without damaging the cells or underlying proteins.

Removing Too/Marks by Skinning MRATs.

The milling method described herein, is suitable for rapid prototyping of devices lacking fine features such as the Star and Microwell MRAT but leaves fine tool marks. To smooth out these tool marks the final MRATs are skinned with PDMS. PDMS is spun at 1500-1700 RPM on glass slides (2×3″×1 mm) creating a thin (100-200 μm) film. The PDMS-M MRATs are briefly pressed into the thin film of PDMS and then placed onto a polystyrene dish and left to cure at room temperature for 24 hours followed by 1 hr at 60° C.

Removing Toolmarks by Replica Molding with PVA.

The above method creates a very smooth bottom surface but widens the MRATs and leaves a thin floppy lip of PDMS at the intersection of the side and bottom of the MRATs. A smooth surface with a clean intersection is achieved without loss of spatial resolution by coating a smooth surface such as glass or mirror-finished metal with a thin film of polyvinyl alcohol (PVA, Partall Film #10, RexCo). MRATs are attached to the PTA film using magnetic force. With the MRATs firmly in place the PVA is washed away with distilled water. After drying, Crystal Clear is cast around the MRATs on the glass or metal and then cured as above. After the Crystal Clear is cured, the MRATs are removed and the remaining PVA is dissolved in water and removed. The resulting negative mold has the smoothness of glass or mirror-finished metal on the bottom, a sharp transition from side to bottom, and the spatial dimensions of the originally machined MRAT and is used to cast MRATs as described above.

Basic Protocol or Star MRAT Migration Experiments:

1) Sterilization. Spray ethanol directly against the contact surface of the MAtS to remove unwanted dust or debris. Then soak the MAtS in 70% ethanol for 10 minutes. Dry the MAtS in an oven (˜60° C.) or under vacuum (−20 mm Hg) to remove any ethanol that may have been absorbed into the MAtS. If simply removed from soaking in Ethanol, MAtS may look dry and still retain ethanol within which will slowly diffuse out into the cell culture medium altering normal cell behavior. 2) Substrates. Coat 6 (or 12) well plates with extracellular matrix proteins (generally Collagen at 100 μg/ml PBS) by incubating the dishes overnight at 4° C. or for 2 h at 37° C. without rotation or shaking. Remove the unbound ECM substrate. (Optional, wash with PBS and block the coated dishes with PBS containing 0.5% bovine serum albumin for 1 h at 37° C.) Then, wash twice with PBS and refill the wells with 1.5 ml or more (750 μl or more for (2-well plates) of media before attaching the MRATs. (It is recommended to either use a lower percentage of serum than that used in the growth media to minimize cell proliferation or plate cells in full growth medium until they adhere to the dish, usually 5-6 hours, followed by overnight serum starvation). Apart from the serum, if the assay is to study the effects of growth factors or other compounds, these soluble factors may need to be included in the media before addition of cells or added to the serum free medium during serum starvation. 3) MRAT attachment. Attach the multi-well plate to the magnet arrangement and place the MAtS into the multi-well plate. In order to avoid damaging the substrate, MRATs should be brought close (1-2 mm) to the substrate and then released allowing the magnetic force to pull them against the substrate. Incubate the assembly of magnets, multi-well plate, and MRATs at 37° C. and 5% CO₂ in order to maintain proper pH in the medium white preparing the cells, 4) Cell preparation. Resuspend subconfluent, growing cells in a tissue culture dish by washing cells twice with PBS, adding trypsin, and incubating until cells have detached. Then mix cells with medium containing serum. Pipette the solution up and down to separate the cells from one another. Take an aliquot from the cell suspension and determine the cell count using a hemocytometer. Plate sufficient cells onto the prepared 6 or 12-well plate to create a confluent monolayer (for 6-well plate: 0.8 million actively growing HEp3 cells or 1 million A549 cells). The required number of cells for a confluent monolayer depends on both the particular cell type and the size of the dish and should be adjusted accordingly. Incubate the dishes properly for 5-16 hr at 37° C. and 5% CO₂ allowing cells to adhere and spread across the substrate. (Optional, cells may be subjected to serum starvation or other conditions for multiple days prior to the initiating the assay. Long incubations may require coating MRATs with pluronic to prevent cell adhesion to MRATs and also decreasing cell quantities to accommodate proliferation during long incubation.) 5) Assay initiation. Remove magnets from the multiwell plate being careful to lift the multiwell plate straight up until it is away from the magnets. Then remove MAtS by carefully lifting the arm of the MAtS so as to avoid any twisting or sliding of the MAtS that would scrape cells off the substrate. Broad-tipped tweezers seem to work better than fine-tipped tweezers for MRATs removal. Change the media as needed. Generally, serum containing medium is added after serum starvation in order to stimulate migration. (Optional, a scratch assay can be performed simultaneously with the MRATs assay. Scrape the cell monolayer with a 200 μl pipette tip in a straight line. Remove the debris and smooth the edge of the scratch by washing the cells once with 2 ml of medium or PBS and then replace with 2-3 ad of medium specific for the assay.) 6) Image acquisition. Automated microscopy in a controlled environment is ideal for repeated observation of multiple locations on each arm of the MRATs; however, highly reproducible results can also be obtained by hand. If acquiring images manually, it is important to repeatedly image the same locations. This can be done by placing a mark on the underside of the plate or by starting from either the end of an arm or the center of the MRATs and capturing 4 or more adjacent images with 1-10% overlap. The image of the end is not usually used to quantify the migration. Timepoints vary depending on the cell type and users objectives such as quantifying migratory effects caused by the initiation and/or the closure of the open space or “wound”. Generally the final timepoint is taken when only 20-30% of the original open space remains because migration generally slows during closure of the final 20%. Before executing a large experiment, the closure time for each cell type is usually determined in order to choose appropriate timepoints. 7) Quantitation. The open area or the cell-covered area is quantified for each timepoint using software such as ImageJ, TScratch, Wimasis, or CellProfiler. If the cell boundaries are aligned parallel to the sides of the image, then an average width can be determined and the change in width used to calculate migration rate in μm/hr. For manual images both sides of the open area or “wound” must be visible in the image in order to quantify the change in the opening. On an automated microscope quantification of the migration rate is possible without capturing both sides of the open area as long as there is no drift of the multiwell plate on the stage or if the drift is corrected for.

Auxiliary Materials Including Holders, Magnets (Composition, Design, Orientation, Application):

Crystal Clear embedded magnet assemblies for guided attachment of MRAT to 6-well plates: Magnetic assemblies suitable for attaching MRATs to any size culture surface including standard P100 culture dishes and 12-well plates can be created. However, the 6-well plate was utilized for development of the MRAT. Neodynium iron-boron magnets 3 mm diameter×1.5 mm (ZD4, K&J Magnets were patterned PVA coated iron plates. The magnetic fields were all aligned in the same direction such that the individual magnets tended to repel each other, but their attraction to the iron plate allowed them to be placed within 0.5 mm or less of each other. They were arranged in groups of 9 magnets. Each group forms a star pattern having 1 magnet in the center and 2 magnets for each of the 4 arms. Then crystal clear was cured on the iron plate encasing and immobilizing the magnets. The crystal clear was cut to fit snugly into the underside of a 6-well plate. Because of the transparent quality of the Crystal Clear, cells can be viewed using phase contrast, likely differential interference contrast as well, and long working distance objectives (≧1.5 mm) without removing the MRAT. This is very beneficial when determining the necessary numbers of cells required to create a confluent monolayer and the time needed for the cells to adhere to the culture surface.

Screw-Clamp Holders for Culture Dishes.

Alternatively, simple screw-clamp holders for multi-well plates have been fabricated from acrylic and teflon screws, CNC machining is used to cut slots 1/16″ deep suitable for holding four bar magnets ¼″×⅛″×⅛″ (B422, K&J Magnetics, Inc). The magnets are glued into the slots having the same magnetic alignment except that it is rotated around the center of the slots. The screw-clamp mechanism secures the plate preventing the magnets from shifting position relative to the plate.

Magnetic Retrieval.

MRATs can be removed magnetically. Two high-grade (N52 according to K&J Magnets) ˜⅜″ diameter NdFeB magnets attached to the handle of a pair of tweezers have been used to remove the MRATs successfully. A device consisting of a lowering and raising mechanism and assembly of magnets could be fabricated to enable simultaneous removal of MRATs from a variety of culture dishes or multi-well plates.

Open-Face Microfluidics.

Many microfluidic devices have been fabricated that require attachment and subsequent removal from a surface. These designs are highly suitable for MRATs because the use of magnetic force eliminates the need for large or complex clamping mechanisms. It has also been determined that magnetic force can hold pressures up to 35 psi in a 70 mm long×7.5 mm wide×1.6 mm high fluidic channel (Marjan Rafat, Lab Chip, 2009, DOI:10.1039/b907957b). The only drawback is that imaging through PDMS-M is not possible, so adaptation of some devices to MRATs would require developing multiphase devices that had the necessary transparent PDMS areas surrounded by PDMS-M. Alternatively, other materials may be used.

Protein Printing (Contact Printing):

Micro-contact printing with PDMS stamps is well established. However, MRATs eliminates the need to apply force from above on the stamp because the magnets provide the force from below. Star or Microwell MRATs can simultaneously pattern cells and proteins in liquids by excluding them while patterning proteins underneath the stencil via contact printing.

Protein Printing (Via Liquid):

The alternative to contact printing is to apply the proteins to the surface in liquid. MRATs can exclude areas, provide patterns via microchannels, and provide reservoirs for the liquids.

Liquid Handling—

Hydrophobic barrier for retaining fluid in a defined space. In the treatment of cells, living or fixated, it is often beneficial to be able to minimize required quantities of reagents by setting up temporary liquid barriers and reservoirs.

Colony Isolation Dam or Selecting Clones.

Another possible immediate field is selection of groups of cells. For example, by plating cells sparsely in a culture dish, colonies from single cells can be grown in distinct groups. MRATs can be placed over a group forming a temporary microwell, which can then be treated with a variety of reagents or even used to trypsinize and remove the cells.

### Example 2

### Cell Migration on User Defined Substrata Using Magnetically Attached Stencils

The application of the magnetic stencils in collective cell migration was demonstrated and highlighted the multifactorial nature of migration. In this example, the requirements for successful patterning of invasive cells on custom substrates were identified. In addition, the maintenance of the custom substrate was verified by fluorescent microscopy, followed by analysis of migration on custom substrates and the interaction of the substrate conditions with i) epithelial-life A549 and mesenchymal-like HEp3 cell lines, ii) protein expression within murine mammary carcinoma cells, and iii) an antibody against CD-151 which inhibits migration in vitro and in vivo. Finally, the unprecedented patterning of collective cell monolayers on polyacrylamide substrates and the collective cell migration that occurs in response to a rigid or flexible substrate.

Methods

Materials:

Small magnets (B422, K&J Magnetics, Inc), large magnets (BXBX84, K&J Magnetics, Inc), PDMS (Sylgard 184, Dow Corning), Magnetite (Pirox 200 custom order washed to remove chlorides, Pirox Inc or magnetite 310069, SigmaAldrich), polyvinyl alcohol (PVA, PartAll Film #10, RexCo), polyurethane two-part resin (Crystal Clear 200, 15 min pot life, Smooth-On), brass (McMaster-Carr), human epidermoid carcinoma (HEp3) cells, human lung carcinoma A549 cells, Dulbecco's Modified Eagle's Medium (DMEM, SigmaAldrich), RPMI-1640 cell culture medium (SigmaAldrich), HEPES, Non-essential amino acids, pyruvate, L-glutamine, pennicilin streptomycin, fetal bovine serum, phosphate buffered saline (PBS), Trypsin, electrical tape, collagen (rat tail type I, BD Biosciences), human plasma fibronectin, polyacrylamide, bis-acrylamide, ammonium persulfate, TEMED, fluorescent beads (2 μm diameter), glass cover slips, Solidworks, GibsCAM, CNC mill, vacuum chamber, oven, Thinky mixer, microRuler.

Cell Culture.

Cell cultures of human epidermoid carcinoma. Hep3, human lung carcinoma A549 cell lines and primary murine mammary carcinoma cells were cultured in DMEM, RPMI and custom-made murine primary cell media respectively. DMEM and RPMI were supplemented with penn/strep, HEPES buffer, non-essential amino acids, and 10% fetal bovine serum. Cells were cultured at 37° C. in a humidified 5% CO₂ incubator and passaged every 2-4 days.

Polydimethylsiloxane Formulation.

Polydimethylsiloxane (PDMS) is made from the Sylgard 184 Silicone Elastomer Kit (Dow Corning). PDMS prepolymer is made by mixing 10 parts base to 1 part curing agent by weight as recommended by the manufacturer (though the ratio can vary significantly to produce more or less crosslinking resulting in stiffer or softer elastomers). This PDMS prepolymer may be degased at this point by vacuum or centrifugation and used as is. However, in most of the applications, ferrimagnetic magnetite powder (iron(II, III) oxide, <5 μm particle size, Sigma-Aldrich, 310069) was mixed into the PDMS prepolymer at a ratio of 2 parts prepolymer to 1 part magnetite by weight which resulted in a mixture that is 33.3% magnetite by weight. The PDMS-magnetite mixture (PDMS-M) can be mixed by hand but a more homogenous mixture was achieved by mixing the PDMS prepolymer and magnetite powder with a rotary mixer (Thinky). When cured the PDMS-M is noticeably stiffer than plain PDMS. Plain PDMS made at the recommended 10:1 ratio has a Young's modulus (elastic modulus) of roughly 750,000 Pa. PDMS mixed with magnetite is noticeably stiffer. The PDMS-M was cured for at least 48 hours at room temperature.

Mold Production.

Four positive brass reliefs were created using a CNC mill with tolerances of less than 30 μm. In order to facilitate release of polyurethane resin from the brass without introducing artifacts from aerosol mold releases, all of the brass except for the positive relief of the MAtS was coated with polyvinyl alcohol (PVA). After drying the PTA, polyurethane resin was cast over the brass creating a negative mold. From the negative polyurethane mold an initial set (≧6) of MAtS were created. These MAtS had tooling marks on all surfaces. To remove tooling marks from the contact surfaces, a thin film of PVA was dried onto mirror-finish stainless steel. MAtS were subsequently sealed against the PVA film with 1.5″×1.5″×¼″ grade N42 magnets (BXBX84, K&J Magnetics, Inc). Then the assembly was washed for 2 minutes in gently running distilled water to remove all the PVA except for the PVA sandwiched between the MAtS and stainless steel. Excess water was blown away and the assembly was dried. A 5-8 mm wall was made around the stainless steel using two-layers of electrical tape in order to contain the polyurethane resin. Polyurethane resin was poured onto the stainless steel surrounding the sandwich of MAtS, PVA, and stainless steel. After curing the polyurethane at room temperature for 48 hours, the magnets and MAtS were removed. The remaining PVA was removed with water and PDMS-M was cast in the mold, degased for 2-3 minutes, and allowed to cure at room temperature for 48 hours or more. The resulting MAtS had minor-finish contact surfaces. Some of these MAtS from the hybrid mold were used to cast additional molds of solid polyurethane.

Design and Dimensions:

Star MAtS were designed with the following dimensions: 10 mm maximum width, 4 arms 4 mm long and 700 μm wide, 5 mm total height. This width of the arms is similar to the mean width of scratches made with a 200 μl pipette tip and compatible 10× objectives on most microscopes. Dot MAtS were also developed for high-throughput and microwell MAtS for studies requiring small quantities of cells or low cell-to-volume ratios. Interestingly, the observed average width for the MAtS was 689.2 μm. This shrinkage of 10.8 μm matches the 1.5% shrinkage predicted for room-temperature curing.

Magnetic Force:

The magnetic force varies controllably with the strength of the magnet, amount of ferromagnetic material in the stencil, and the distance between the magnet and stencil. Different magnetic arrangements were tested for their ability to facilitate alignment of the MAtS. The arrangement of four magnets rotated by 90° around a central point but otherwise identical in alignment was chosen because of its ability to facilitate alignment of star MAtS. Force requirements were evaluated with a practical approach but not quantified. Different strength magnets were used with similar MAtS to block the aggressive HEp3 cancer cells and prevent protrusions and ultimately the ¼″×⅛″×⅛″ grade N42 neodymium-iron-boron (NdFeB) magnets were chosen for use (B422, K&J Magnetics, Inc). The space between magnets and MAtS for 6-well plates alone was 2 mm. Glass cover slips (22 mm diam) were placed in 6-well plates, coated with substrates, and then protected with MAtS while cells adhered. The glass cover slips added about 150-170 μm to the distance between magnets and MAtS. For the cell protrusion study a custom-built sealed chamber was used. The distance between MAtS and the medium magnets was 900 μm.

MAtS Preparation and Sterilization:

To prepare MAtS for use in collective cell migration assays, excess PDMS-M was removed from the tops of the MAtS with a clean razor blade. The contact surface of MAtS was then sprayed vigorously with 70% ethanol. Excess ethanol was aspirated from the surface of the MAtS in the cell culture hood following which MAtS were placed upside down to dry. In addition to sterilizing the MAtS the vigorous spraying also helps remove dust or debris that may have inadvertently gotten on the contact surface of the MAtS. MAtS may also be soaked in 70% ethanol for 10 minutes or more after which they must be dried in an oven at 50-60° C. for 1 hour or more in order to evaporate any ethanol from within the PDMS-M.

Collective Cell Migration.

Collective cell migration studies performed by scratch followed the protocol of Liang et al. (Liang, et al. (2007). “In vitro scratch assay: a convenient and inexpensive method for analysis of cell migration in vitro.” Nature Protocols 2(2): 329). The scratch assay used for the collective cell migration measurements; was modified to include the following steps for MAtS using a 6-well plate. Magnets were securely affixed underneath the 6-well or 96-well plate. Medium was added to the wells: 1-2 ml for a 6-well plate. Then MAtS were positioned slightly above the culture surface and released allowing the magnetic force to pull them down. For both scratch and MAtS assays cells were added drop by drop to achieve a total quantity per well of 800,000. After incubating for 16 hours or more, the cells were washed with PBS. Then the magnets and MAtS were removed in that order. For the A549 experiment scratches were made alongside the cells patterned with MAtS. Then the cells were washed again and fresh culture medium was added. Images were taken immediately and at given times (8, 12, and/or 24 hours) post MAtS removal. In the above protocol, volumes and cell numbers were modified to accommodate the different surface area of glass cover slips.

Protein Patterning.

Protein patterns were created with MAtS as follows. Tissue culture plastic was coated with 100 μg/ml FITC gelatin and rinsed three times with PBS. Then MAtS were positioned slightly above the coated plastic surface and released allowing the magnets to pull the MAtS against the surface. PBS solution containing 3 μg/ml human plasma fibronectin was added and incubated around the MAtS for 2 hour at 37° C. After rinsing three times with PBS, the magnets and MAtS were removed, and the culture surface was rinsed two more times with PBS. Rabbit antibodies were then added against human fibronectin at 2 μg/ml and incubated for 1 hour at 37° C. The surface was rinsed, and an anti-rabbit goat antibody labeled with Alexa 546 was added for 1 hour at 37° C. After rinsing three times with PBS, the surface was imaged.

Elastic Polyacrylamide Substrates:

Briefly, 8% acrylamide and 0.05% bis-acrylamide (soft) and 0.35% bis-acrylamide (hard) were crosslinked using ammonium persulfate and TEMED. Small rectangles of 170 μm PDMS membranes were used as spacers for the glass cover slips used to sandwich the gel while it polymerized. The polyacrylamide surface was with 1% gelatin for 10 minutes, then the gelatin was aspirated and dried in the vertical position for 30 minutes. The gelatin was crosslinked with 0.5% glutaraldehyde in PBS for 45 minutes, washed repeatedly with PBS over a 15 minute period. Sodium-borohydride at 1 mg/ml was added for 1-2 minutes to quench the fluorescence of the glutaraldehyde and washed repeatedly with PBS over a 15 minute period. At this point the substrate was used following the collective cell migration procedure above. The elastic modulus of this hard polyacrylamide is 10 kPa which is similar to the elastic modulus of muscle tissue.

Data Acquisition and Quantification:

For both MAtS and Scratch assays data was acquired as images from phase contrast and/or fluorescent microscopes showing the distance between the two opposing monolayers created by MAtS or by scratch assays. The open space between cell monolayers was quantified as a percentage of the total image area using TScratch. Since the images were taken so that the boundary of the wound was parallel to the edge of the image, it could be assumed that the height of the wound was equal to the height of the image (height_wound=height_image). This assumption reduced the equation, percent_area=(width_wound*height_wound)/(width_image*height_image), to the following: width_wound=width_image*percent_area/100.

Using these assumptions the migration rate was calculated as rate=(width_wound_timeB−width_wound_timeA)/(timeB−timeA) where the widths are given in microns and the time is given in hours to create a rate in microns per hour. It is important to note that this rate of closure represents the rate achieved by two monolayers moving towards one another and may therefore differ by a factor of two from similar migration of single cells.

Statistics and Graphs:

Most of the data was analyzed using R (www.r-project.org/). All reported p-values were determined using the Welch Two Sample t-test in R (t.test). All box and whisker plots were made using R's default statistical settings of the boxplot command. The box shows the 25th, 50th, and 70th percentiles and the whiskers extend to the most extreme data point which is no more than 1.5 times the interquartile range from the box which shows the extremes. In order to show the richness of the data, individual datapoints were overlaid onto the boxplot using the stripehart command. GraphPad Prizm was used to create the plot of distance versus time showing means and standard deviations.

Results:

Stencil Design and Development:

Magnetically attachable stencils (MAtS) resulted from the realization that magnetic force could be used to attract a stencil against a wet, protein-coated surface and thus overcome limitations of other cell-blocking techniques. Using magnetite, a magnetically attachable stencil was designed so that it is attracted to and held in contact with a culture surface via magnetic force from magnets placed under the culture surface. The magnetic force between stencils and magnets is consistent and controllable.

By varying the distance between MAtS and magnets, the magnet strength, or the amount of magnetite in the MAtS the force can be tailored to the application. This force ensures that the MAtS attach regardless of substrate conditions.

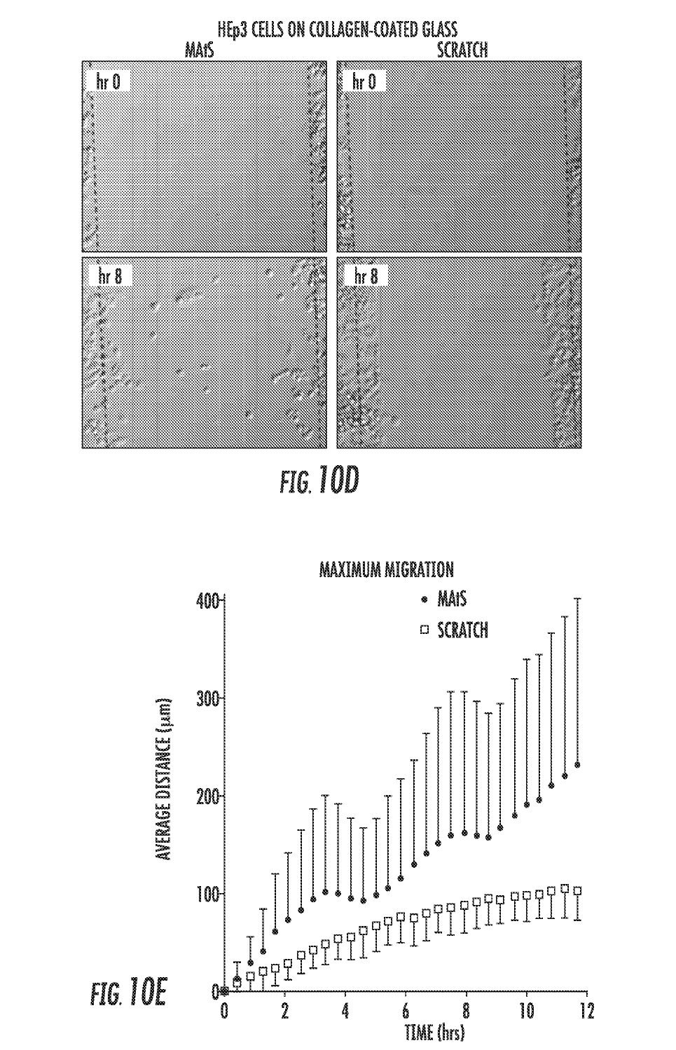

Though designs already constructed as in Example 1, for high-throughput MAtS and low-cell-quantity MAtS, in this example, the general purpose star design was employed. These star MAtS create cell monolayers that resemble the intersection of two perfect, perpendicular 700 μm wide 10 mm long scratches (FIG. 10A). Because of their similarity to the traditional scratch assay, MAtS can be used with the same culture conditions, surfaces, cell quantities, data acquisition, and quantification methods.

Micro-Scale Precision:

Some cell types such as epithelial-like A549 cells are easily patterned; however, more invasive cells like HEp3 cells can be difficult to pattern because of their tendency to protrude into small crevices. Therefore, achieving micron-scale resolution on the contact surface and edge of MAtS was essential to successfully patterning different cell types. Initial MAtS prototypes had fine toolmarks due to machining of the brass relief. Removing the toolmarks by buffing the brass created curvature on the contact surface which promoted cell protrusions. Coating the contact surface of MAtS with a thin layer of PDMS created a smooth flat surface with a lip which did not seal reproducibly against the substrate. Unexpectedly the challenge of preventing cell protrusions became similar to one of the major challenges of microfabrication: how to combine micro-scale features on macro-scale (>1 mm) structures.

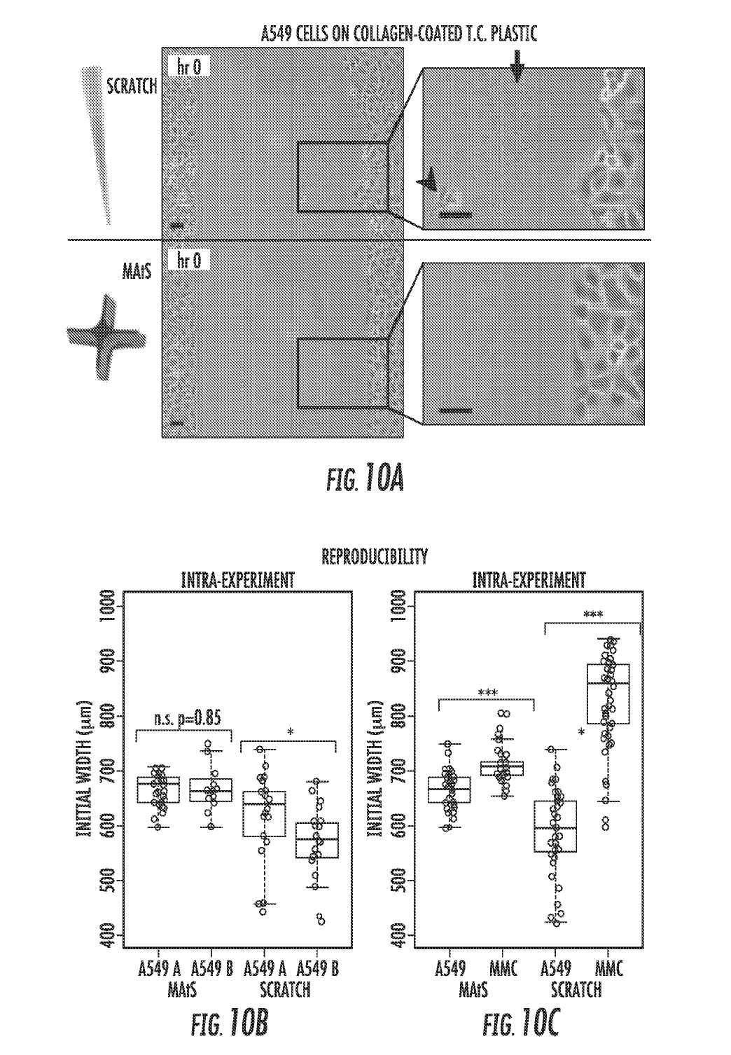

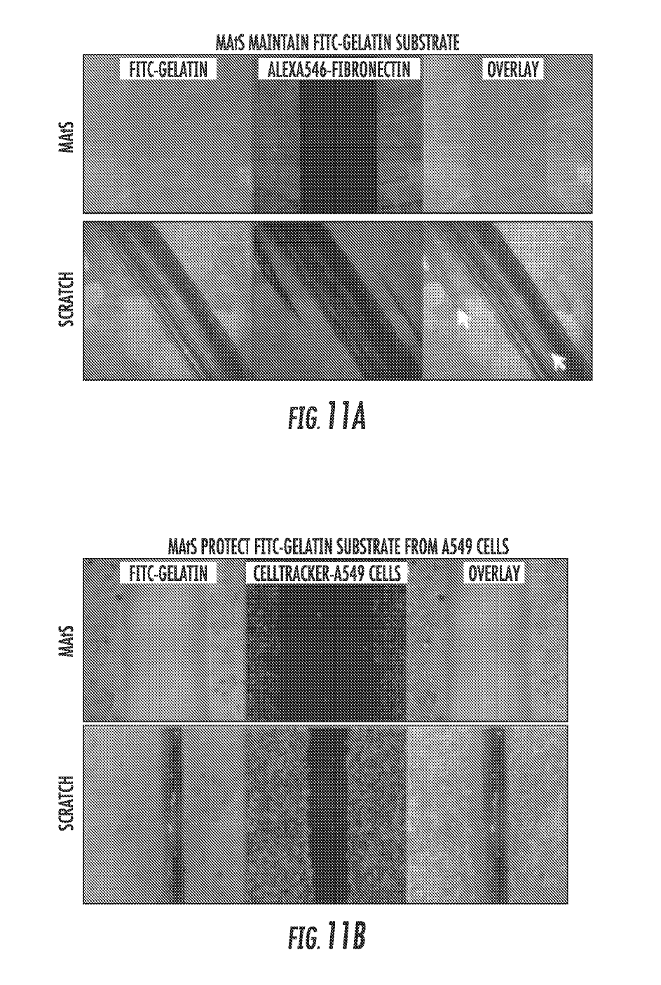

Recognizing the similarity between our mold production and fabricating microfluidic devices, techniques from the microfabrication field were used to develop hybrid polyurethane/stainless steel molds that replaced the toolmarks of the initial MAtS with the mirror-finish surface of the stainless steel (FIG. 9A). The methods section gives details for hybrid mold fabrication. The resulting MAtS have flat, mirror-finish contact surfaces that precisely intersect with the sidewalk rather than being curved from buffing or having a lip from a thin coating of PDMS. These MAtS successfully patterned HEp3 cells on collagen-coated tissue culture plastic preventing protrusions even after 24 hours of incubation. However, toolmarked MAtS allowed cells to protrude into the void. Some cells protruded almost entirely (arrow), but minor protrusions were more common (arrowheads, FIG. 9B). In order to better visualize cell behavior at the interface with MAtS, the surface of MAtS was labeled with Alexa 546 goat anti-rabbit antibody and collected z-stacks using a spinning disk confocal microscope (FIG. 9C). The resulting 3D reconstruction revealed that these small protrusions enabled cells to pull closer to and touch the sidewalls of the initial MAtS prototypes. On the other hand successful prevention of cell protrusions resulted in less frequent contact between the cells and sidewalk of the MAtS (FIG. 9C). The ability of MAtS to seal against the substrate was further highlighted when the effect of MAtS on the substrate was examined (FIG. 11A). In order to visualize the area occupied by the MAtS on FITC gelatin coated tissue culture plastic, fibronectin was added while the MAtS were attached. The smooth border of the fibronectin (shown in red) evidences that MAtS seal off the substrate preventing fluids from diffusing into the underlying space (FIG. 11A). These results show that toolmarks were successfully eliminated from the contact surface of the MAtS enabling a tight seal between the MAtS and custom-coated substrates which successfully blocks protrusions from aggressive HEp3 cancer cells and successfully patterns proteins in solution.

Reproducible Cell Monolayers and User-Defined Substrates:

The successful integration of microscale precision with the macroscale dimensions of MAtS translated into decreased deviation and greater reproducibility of the initial wound width (FIGS. 10B-10C). Scratches inherently create variation in the borders of the remaining cell monolayer and in the substrate conditions. FIG. 10A shows common substrate roughness (arrow) and debris (arrowhead) left even after rinsing the scratched A549 cell monolayers on collagen-coated plastic. MAtS increase reproducibility of cell monolayer boundaries and maintain substrate conditions.

The reproducibility between replicates of specific experiments (intra-experimental reproducibility) and between different cell types (inter-experimental reproducibility) was investigated. To analyze the intra-experimental reproducibility of MAtS, experiments were performed on different dates and then compared two otherwise identical experiments with A549 cells on collagen-coated plastic. Initial widths from MAtS were practically indistinguishable for the two experiments, A549 A and A549 B (p>0.8, FIG. 10B) and showed small standard deviations of 27.8 and 42.8 μm respectively. In order to place these results into a more common context, scratch assays were performed alongside each experiment. Initial widths from scratch assays varied significantly despite maintaining the same experimental parameters and removing all outliers caused by scratching toward rather than away from oneself. The standard deviations for the scratches were 81.6 and 62.7 μm respectively (FIG. 10B).

Inter-experimental reproducibility was analyzed in a similar manner by comparing the combined A549 A and A549 B data (n≧45) to a similar experiment (n≧47) with murine mammary carcinoma cells which are also epithelial-like. MAtS increased similarity of the initial widths of A549 and MMC's to within 50 microns of each other. Surprisingly, however, the initial widths were still highly significant (p<0.001) due to the distinct adhesive properties of A549 and MMC cells (FIG. 10C). These adhesive differences were magnified by physically scratching away parts of the monolayer.

In order to perform time-lapse microscopy of collective migration, cells were plated onto collagen-coated glass cover slips. The resulting migration of HEp3 cells revealed a fundamental difference between migration on glass and tissue culture plastic. Cells patterned with MAtS were able to migrate across the collagen-coated coverslip; however, scratching prevented cells from migrating into the central area. After reaching a fixed distance, HEp3 cells stopped migrating or changed direction to migrate along on unseen line (FIGS. 10D, 10E). Interestingly, A549 cells migrated continuously on both collagen-coated glass blocked by MAtS and glass denuded of cells with a scratch. Since A549 cells are highly capable of making their own matrix but HEp3 generally do not, the most logical explanation for this stark inability of HEp3 cells to migrate into areas denuded by scratch is that the matrix was also removed.

In order to verify that MAtS maintain custom substrates, tissue culture plastic was coated with FITC-labeled gelatin, attached MAtS, and either coated around the MAtS with human fibronectin or with A549 cells (FIGS. 11A, 11B respectively). The substrate underneath the MAtS was maintained with little to no alterations as seen by coating around the MAtS with fibronectin (FIG. 11A top). Scratching this substrate removed the majority of both the gelatin and fibronectin; although, in some areas the gelatin remained but not the fibronectin (arrows FIG. 11A bottom). However, when A549 cells (labeled with CellTracker Red) were added, proteases degraded the matrix in tight spots underneath the cells and more diffusely along the interface of the cells and MAtS (FIG. 11B). Scratching, as anticipated, removed most but not all of the substrate around the cells (FIG. 11B). This incomplete loss of substrate explained the inhibited migration observed in FIGS. 10D, 10E.

Integrating Multiple Factors of Migration:

In vitro and in vivo studies show that environmental conditions such as matrix composition and elastic modulus have significant effects on cell behavior. Accordingly, MAtS was utilized to analyze in terms of migration the integration of cellular stimuli. Specifically, migration resulting from the lack or presence of collagen was analyzed on tissue culture plastic using 1) different cell types (FIGS. 11A, 11B), 2) identical cells with different protein expression, 3) and HEp3 cells with anti-CD151 antibody that inhibits migration in a matrix dependent manner. Also demonstrated, was the ability to pattern cells and analyze migration on alternating lanes of proteins and on elastic polyacrylamide substrates.

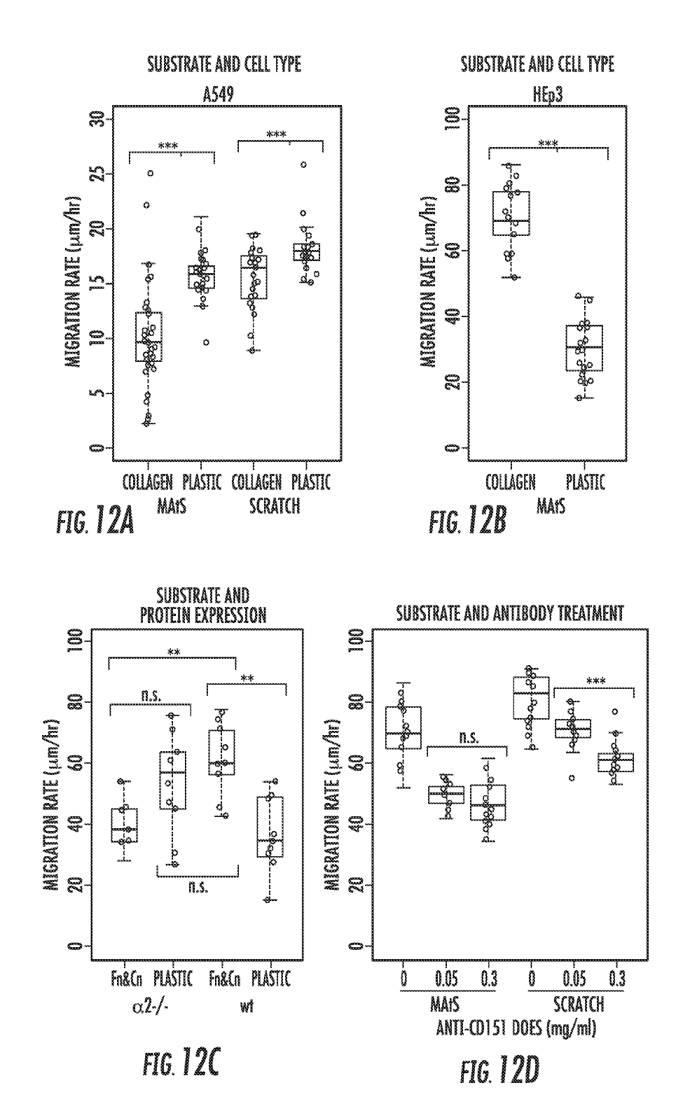

Cells respond differently to substrate conditions according to their unique protein expression. Migration of epithelial-like A549 and mesenchymal HEp3 cells in response to collagen or the lack of collagen on tissue culture plastic (FIGS. 12A, 12B) were analyzed. These two cell lines displayed opposite behaviors in response to the change in substrate conditions. A549 cells migrated faster on tissue culture plastic than on collagen (FIG. 12A), but HEp3 cells slower on tissue culture plastic than on collagen (FIG. 12B). As expected from the analysis of substrate conditions after scratching, the A549 monolayer scratched on collagen coated tissue culture (t.c.) plastic had migration rates very similar to those of MAtS on t.c. plastic and scratched t.c. plastic (FIG. 12A). A549 and HEp3 cells have many differences in terms of protein expression; however, similar opposing changes in migration rate were observed for MMC's from wild-type and integrin alpha2 knockout mice (FIG. 12C). Cells lacking alpha2 migrated faster on t.c. plastic than on fibronectin and collagen. On the other hand cells expressing normal levels of alpha2 migrated slower on t.c, plastic than on fibronectin and collagen (FIG. 12C). These results with two different cell types and with cells expressing different levels of integrin alpha2 evidence that migration results from protein expression within the cell.

However, external factors also combine with substrate conditions to determine cell migration. After patterning HEp3 cells with MAtS collagen-coated t.c. plastic, anti-CD151 antibody was administered at low (50 μg/ml) and high (300 μg/ml) doses and initiated migration. Under MAtS were the substrate remained intact, inhibition was evident at the low dose and migration rates were reduced significantly. In fact the low and high doses were incredibly similar using MAtS. To provide a meaningful context for these results, part of the cell monolayer in this experiment was scratched. The efficacy of anti-CD151 was significantly reduced by scratching especially for the low dose (FIG. 12D) highlighting the importance of the substrate not only when dealing with different cell protein profiles but also when using a single cell type. These results evidence the multifactorial, context-dependent nature of migration.

The above studies were relatively simple in order to validate MAtS as a novel tool for studying cell migration; however, MAtS were developed to enable more complex studies of migration.

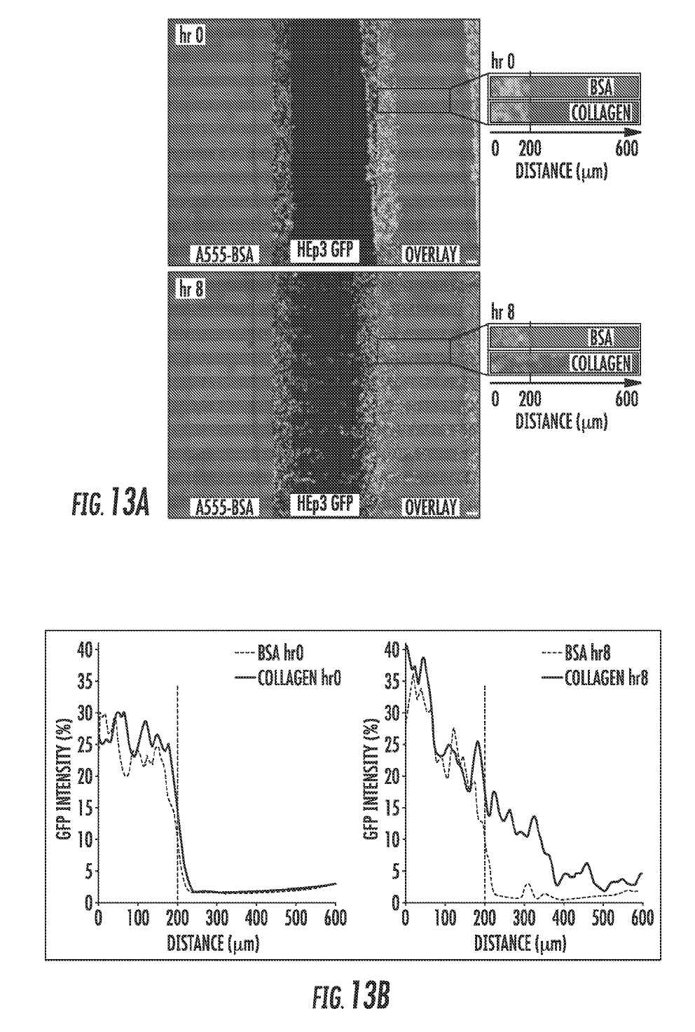

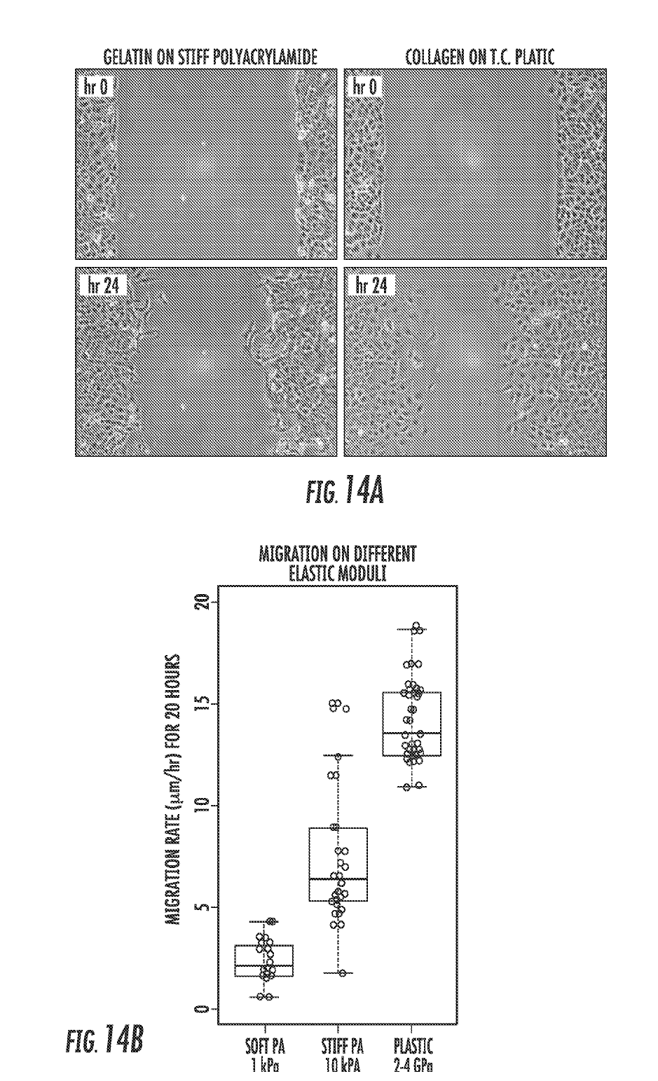

The two following experiments provide proof of concept for more advanced studies with MAtS. In the first experiment, using a magnetically attachable stencil patterned with parallel microfluidic channels, alternating lanes of collagen (dark red) and bovine serum albumin (bright red, FIG. 13A) were patterned. Then star MAtS were used to pattern HEp3 GFP cells (green, FIG. 3A) and initiate migration on the alternating lanes. HEp3 cells migrated preferentially on collagen which was quite apparent after 8 hours (FIGS. 13A, 13B). The MAtS' consistent, controllable magnetic force is key to maintaining substrates on rigid plastic or glass but can also be applied to elastic substrates. In the second experiment, MAtS was used to pattern A549 cells on gelatin-coated polyacrylamide gels. The MAtS successfully patterned A549 cells on the gel without disrupting the gel or gelatin coating, and A549 cells displayed altered morphology in response to the elasticity of the gel (FIG. 14A). The resulting migration was significantly slower on the elastic polyacrylamide gel than on collagen-coated plastic (see FIG. 14B). This is the first application of a cell blocking technique to study cell migration on elastic substrates.

Discussion:

By mixing magnetite into PDMS, stencils were attracted to magnets but had to be made much thicker (5 mm) to generate sufficient force. Because of the height, mill brass reliefs of the MAtS were used rather than photolithography to make the molds. The toolmarks left from machining enabled cell protrusion and promoted attachment to the MAtS, microfabrication, sacrificial layers are frequently employed to enable patterned etching or growth of a material. This was adopted for the fabrication and used polyvinyl alcohol (PVA) as a thin sacrificial layer on mirror finish stainless steel to make hybrid molds of polyurethane and stainless steel with mirror finish surfaces for the critical contact surface of the MAtS. The resulting MAtS successfully pattern cells preventing cell protrusions, maintain virgin custom substrata, and pattern proteins in solution. Custom substrates include standard matrix proteins and also soft and stiff substrates of polyacrylamide.

Several advantages of MAtS arise from the consistent, reproducible force between the magnets and MAtS. First, releasing MAtS in fluid before they touch the substrate allows the magnets to pull the MAtS down. This eliminates the risk of accidentally scraping the substrate with the MAtS. Second, the force can be easily adjusted by varying the distance between MAtS and magnets or switching to different magnets. This enables the force to be customized for different assays. This ability will be especially important when developing protocols to attach MAtS to a variety of elastic substrata. Lastly, the magnetic force can be used to align and attach MAtS without any user-intervention. Though data are not shown in this example, the magnetic force has been used to successfully orient and attach cylindrical MAtS in a 96-well plate. The ability of MAtS to pattern cells and allow migration on virgin, user-defined substrates relies on these unique advantages.

Another important advantage of MAtS assays is the versatility of the systems. Magnets can be placed under nearly any culture surface. Because of this MAtS can be used in scratch assay protocols without having to switch culture surfaces or modify fluid volumes, cell numbers and so on. Nevertheless, there are two necessary changes. First, the MAtS must be attached prior to adding cells, and second, the magnets and MAtS must be removed when the cells would normally be scratched. Of course cells can also be scratched and data collected for both MAtS and scratch assays. The user when working with delicate substrates such as collagen or fibronectin coatings can: 1) add cell culture medium to a height of at least 2 mm, 2) position and release the MAtS 2-3 mm above the substrate, 3) finally add the cells drop by drop so they are distributed evenly around the MAtS. These differences in protocol are minor and allow MAtS to be readily adopted to all areas of study currently employing scratch assays.

In this example, both the important biological proofs of concept and novel applications of MAtS were demonstrated. MAtS successfully patterned epithelial-like A549 cells and mesenchymal HEp3 cells. MAtS successfully patterned cells and blocked cell protrusions. Reproducibility of the initial width was greatly increased when using MAtS compared to scratching. MAtS protected the virgin, user-defined substrate as seen directly by visualization FITC-gelatin on glass and plastic both with and without cells. Knowing that MAtS successfully patterned cells while simultaneously protecting the substrate, factors involved in migration were investigated.

Migration is a multi-factorial, context-dependent process in which the substrate plays a key role. The importance of the substrate was demonstrated for different cell types, cell lines with different protein expression, and cells undergoing different treatments. In all cases the substrate conditions significantly changed migration rates. It was observed that HEp3 cells and A549 cells had opposition reactions when migrating on collagen compared to t.c. plastic. HEp3 cells decreased their rates on collagen while A549 cells migrated faster on collagen. Similar opposing changes in migration rate were observed for murine mammary carcinoma cells either lacking or expressing wild-type levels of integrin α2. Also shown was that sensitivity to inhibitors of migration can be greatly increased by the presence of matrix proteins. These experiments highlight the importance of maintaining a relevant substrate during in vitro migration studies.

By maintaining in virgin condition a user-defined substrate, MAtS enable more serious in vitro analysis of environmental components involved in in vivo cell migration during, development, healing, and disease. By coating glass or plastic with combinations of matrix proteins and/or cell-cell adhesion molecules, the individual contributions of these factors can be investigated in the context of collective cell migration.

MAtS also enable more complex experiments which were demonstrated with two experiments. First, alternating lanes of collagen and bovine serum albumin conjugated to Alexa555 were patterned with a magnetically attachable microfluidic device. The resulting distribution of HEp3 cells as they migrated shows the preference for collagen over albumin. The result shows that more complex studies are practical. By patterning proteins with microfluidics, gradients or alternating lanes of two different matrix proteins or cell-cell adhesion molecules can be created. Migration across such substrates will reveal migratory preferences and more importantly show the effect of the smooth or step-wise gradient on collective cell migration. MAtS will also open the door to collective cell migration studies of these haptotactic effects which until now have primarily been studied in the context of single cell migration. Second, cells were patterned on elastic polyacrylamide substrates for studies of collective cell migration. This important proof of concept pushes the door wide open for converting studies on soft and stiff substrates such as durotaxis and invadapodia from single cell to collective cell. Currently, the only way to achieve durotaxis studies of collective cell migration is limited to cells that readily grow colonies.

These results suggest that the physical wounding of the cell monolayer stimulates migration. When comparing, MAtS and scratch assays on uncoated t.c. plastic, scratches created significantly higher rates of migration. MAtS may be used to deter determine if this increase results from physical wounding of the cell monolayer. Modifying PDMS surfaces is a common practice in the field of microfluidics. Modifications to block protein adsorption and cell adhesions have also been achieved with Pluronics and poly(2-hydroxy-ethylmethacrylate) (poly-HEMA). The most interesting of these methods to prevent protein adsorption mixed the pluronic into PDMS prepolymer and after fabricating devices drew the pluronic to the surface by immersion in water. Using these techniques the side surfaces of MAtS alone can be modified to inhibit or promote cell adhesion. The wounding from these MAtS could be directly observed by increased initial widths and used to determine the effect of physically wounding the monolayer on cell migration. Surface modification of MAtS provides a unique opportunity to quantify the subtle effects of wounding on the migration of collective cell monolayers.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The Abstract of the disclosure will allow the reader to quickly ascertain the nature of the technical disclosure. It is submitted with the understanding that it will not be used to interpret or limit the scope or meaning of the following claims.

1-62. (canceled)

63. A system for attaching a removable template for purposes of molding, shaping, patterning, printing, separating, and retaining biological and non-biological delicate materials formed on a surface of a culture unit, comprising:
a magnetic reversibly attachable template comprising an elastomer containing magnetic particles and having at least one of a divider and a protruding member, at least one of the divider and the protruding member comprising smooth and flat contact surfaces for contacting and sealing at least a portion of the delicate underlying material; and
at least one magnet arranged with respect to the template so as to orient the template in a fixed position and to reversibly attach the template to the culture unit via a magnetic force between the template and the at least one magnet, wherein the magnetic force is insufficient to damage the delicate materials.

64. The system of claim 63, wherein at least one of a magnetic field of the at least one magnet and a distance of the at least one magnet with respect to the template are adjustable.

65. The system of claim 63, wherein the at least one magnet comprises at least one of a permanent magnet, a temporary magnet or an electromagnet.

66. The system of claim 63, wherein the at least one of the divider and the protruding member further comprises sidewalls intersecting the contact surfaces.

67. The system of claim 66, wherein the sidewalls intersect the contact surfaces without curvature or a lip.

68. The system of claim 63, wherein the elastomer comprises at least one of polydimethylsiloxane, polymethylmethacrylate, polyacrylic acid, polyacrylamide, polymethacrylamide, polyethacrylamide, polyalkacrylamides, polyamides, polyacrylonitrile, polybutadiene, polycaprolactone, polyethylene, polypropylene, polystyrene, polydivinylbenzene, polyethylene glycol, polypropylene glycol, polylactide, polyglycolide, polyornithine, polyvinyl acetate, polyvinyl alcohol, polyvinyl chloride, polyvinyl isobutyl ether, polyvinyl methyl ether, polyurethane, and polyvinylpyrrolidone, polymeric organosilicon, copolymers thereof, polytetrafluoroethylene, poly(p-xylylene) polymers, and rubber.

69. The system of claim 63, wherein the magnetic particles comprise at least one of ferromagnetic, ferrimagnetic, paramagnetic, or superparamagnetic particles.

70. The system of claim 63, wherein the magnetic particles are between about 0.0001 μm to about 50 μm in diameter.

71. The system of claim 63, wherein the template comprises a composition that is between 2% and 50% magnetic particles by weight.

72. A method for molding, shaping, patterning, printing, separating, and retaining biological and non-biological delicate materials formed on a surface of a culture unit, comprising:
providing a magnetic reversibly attachable template comprising an elastomer containing magnetic particles and having at least one of a divider and a protruding member, the at least one of the divider and the protruding member comprising smooth and flat contact surfaces;
approaching the culture unit with the template; and
applying a magnetic force to the template so as to orient the template in a fixed position and to reversibly attach the template to the culture unit,
wherein the attaching causes the contact surfaces to contact and seal at least a portion of the delicate materials, and
wherein the magnetic force is insufficient to damage the delicate materials.

73. The method of claim 72, further comprising applying contact or liquid printing to transfer a pattern of the contact surfaces to the culture unit.

74. The method of claim 72, wherein the applying comprises:
arranging at least one magnet with respect to the template and the culture unit to provide the magnetic force; and
selectively adjusting at least one of a magnetic field of the at least one magnet and a distance of the at least one magnet with respect to the template.

75. The system of claim 74, wherein the at least one magnet comprises at least one of a permanent magnet, a temporary magnet, or an electromagnet.

76. The method of claim 72, further comprising utilizing the template, when reversibly attached to the culture unit, to form a chamber, wherein the chamber comprises at least one of void space, a micro well, a three-dimensional culture space, a fluid barriers, a movable flap, a porous divider, a microfluidic channels, or a micro-printed pattern.

77. The method of claim 72, wherein providing the template further comprises selecting the at least one of the divider and the protruding member to have sidewalls intersecting the contact surfaces without curvature or a lip.

78. The method of claim 72, wherein providing the template comprises configuring at least one of the divider and the protruding member to have at least one of a molecular coating, a chemical coating, or a protein coating to control interaction with adjacent cells.

79. The method of claim 72, wherein providing the template further comprises selecting the elastomer to comprise at least one of polydimethylsiloxane, polymethylmethacrylate, polyacrylic acid, polyacrylamide, polymethacrylamide, polyethacrylamide, polyalkacrylamides, polyamides, polyacrylonitrile, polybutadiene, polycaprolactone, polyethylene, polypropylene, polystyrene, polydivinylbenzene, polyethylene glycol, polypropylene glycol, polylactide, polyglycolide, polyornithine, polyvinyl acetate, polyvinyl alcohol, polyvinyl chloride, polyvinyl isobutyl ether, polyvinyl methyl ether, polyurethane, and polyvinylpyrrolidone, polymeric organosilicon, copolymers thereof, polytetrafluoroethylene, poly(p-xylylene) polymers, and rubber.

80. The method of claim 72, wherein providing the template further comprises selecting the magnetic particles to comprise at least one of ferromagnetic, ferrimagnetic, paramagnetic, or superparamagnetic particles.

81. The method of claim 72, wherein providing the template further comprises selecting the magnetic particles to be between about 0.0001 μm to about 50 μm in diameter.

82. The method of claim 72, wherein providing the template further comprises selecting the template to have a composition is between 2% and 50% magnetic particles by weight.
